(19) United States
(12) Patent Application Publication
(10) Pub. No.: US 2016/0268500 A1
(43) Pub. Date: Sep. 15, 2016

(54) RESISTANCE CHANGE MEMORY

(71) Applicant: KABUSHIKI KAISHA TOSHIBA, Tokyo (JP)

(72) Inventors: Hironobu FURUHASHI, Kuwana Mie (JP); Kenji AOYAMA, Yokkaichi Mie (JP)

(73) Assignee: KABUSHIKI KAISHA TOSHIBA, Tokyo (JP)

(21) Appl. No.: 14/836,505

(22) Filed: Aug. 26, 2015

Related U.S. Application Data
(60) Provisional application No. 62/130,461, filed on Mar. 9, 2015.

(51) Int. Cl. H01L 43/08; H01L 43/12

(52) U.S. Cl. CPC H01L 43/08; H01L 43/12; H01L 43/10

(57) ABSTRACT

According to one embodiment, a resistance change memory includes first and second semiconductor pillars on a conductive region, a first word line including a first portion surrounding a side surface of the first pillar, a second portion surrounding a side surface of the second pillar, and a third portion connecting between the first and second portions, the first and second portions being physically separated from one another, a first resistance change element connected to an upper portion of the first semiconductor pillar, and a second resistance change element connected to an upper portion of the second semiconductor pillar.

### CROSS-REFERENCE TO RELATED APPLICATIONS

This application claims the benefit of U.S. Provisional Application No. 62/130,461, filed Mar. 9, 2015, the entire contents of which are incorporated herein by reference.

### FIELD

Embodiments described herein relate generally to a resistance change memory.

### BACKGROUND

A resistance change memory such as a magnetic random access memory (MRAM) is promising as a high-speed, large-capacity next-generation nonvolatile memory. A memory cell of the resistance change memory comprises a resistance change element and a cell transistor.

In general, however, the cell transistor comprises a source/drain exposed to a surface of a semiconductor substrate. For this reason, a contact is required for the source/drain in each memory cell. As a result, the area necessary for each memory cell becomes large.

Thus, use of a vertical transistor as the cell transistor is reviewed. Since the vertical transistor does not require a contact for the source/drain, the transistor is expected to reduce the area necessary for each memory cell.

### BRIEF DESCRIPTION OF THE DRAWINGS

FIG. 1 is a bird's eye view showing a memory cell array of a resistance change memory.

FIG. 2 is a plan view showing the memory cell array of the resistance change memory.

FIG. 3 is a cross-sectional view seen along line in FIG. 2.

FIG. 4 is a cross-sectional view seen along line IV-IV in FIG. 2.

FIG. 5 is a plan view showing the resistance change memory shown in FIG. 2 omitted partially.

FIG. 6 is a cross-sectional view seen along line VI-VI in FIG. 5.

FIG. 7 is a cross-sectional view seen along line VII-VII in FIG. 5.

FIG. 8 is a plan view showing the memory cell array of the resistance change memory.

FIG. 9 is a cross-sectional view seen along line IX-IX in FIG. 8.

FIG. 10 is a cross-sectional view seen along line X-X in FIG. 8.

FIG. 11 is a plan view showing the memory cell array of the resistance change memory.

FIG. 12 is a cross-sectional view seen along line XII-XII in FIG. 11.

FIG. 13 is a cross-sectional view seen along line XIII-XIII in FIG. 11.

FIG. 14 is a plan view showing the memory cell array of the resistance change memory.

FIG. 15 is a cross-sectional view seen along line XV-XV in FIG. 14.

FIG. 16 is a cross-sectional view seen along line XVI-XVI in FIG. 14.

FIG. 17 is a plan view showing the memory cell array of the resistance change memory.

FIG. 18 is a cross-sectional view seen along line XVIII-XVIII in FIG. 17.

FIG. 19 is a cross-sectional view seen along line XIX-XIX in FIG. 17.

FIG. 20 is a plan view showing the memory cell array of the resistance change memory.

FIG. 21 is a cross-sectional view seen along line XXI-XXI in FIG. 20.

FIG. 22 is a cross-sectional view seen along line XXII-XXII in FIG. 20.

FIG. 23 is a plan view showing the memory cell array of the resistance change memory.

FIG. 24 is a cross-sectional view seen along line XXIV-XXIV in FIG. 23.

FIG. 25 is a cross-sectional view seen along line XXV-XXV in FIG. 23.

FIG. 26 is a plan view showing the memory cell array of the resistance change memory.

FIG. 27 is a cross-sectional view seen along line XXVII-XXVII in FIG. 26.

FIG. 28 is a cross-sectional view seen along line XXVIII-XXVIII in FIG. 26.

FIG. 29 is a plan view showing the memory cell array of the resistance change memory.

FIG. 30 is a cross-sectional view seen along line XXX-XXX in FIG. 29.

FIG. 31 is a cross-sectional view seen along line XXXI-XXXI in FIG. 29.

FIG. 32 is a plan view showing the memory cell array of the resistance change memory.

FIG. 33 is a cross-sectional view seen along line XXXIII-XXXIII in FIG. 32.

FIG. 34 is a cross-sectional view seen along line XXXIV-XXXIV in FIG. 32.

FIG. 35 is a plan view showing the memory cell array of the resistance change memory.

FIG. 36 is a cross-sectional view seen along line XXXVI-XXXVI in FIG. 35.

FIG. 37 is a cross-sectional view seen along line XXXVII-XXXVII in FIG. 35.

FIG. 38 is a plan view showing the memory cell array of the resistance change memory.

FIG. 39 is a cross-sectional view seen along line XXXIX-XXXIX in FIG. 38.

FIG. 40 is a cross-sectional view seen along line XL-XL in FIG. 38.

FIG. 41 is a plan view showing the memory cell array of the resistance change memory.

FIG. 42 is a cross-sectional view seen along line XLII-XLII in FIG. 41.

FIG. 43 is a cross-sectional view seen along line XLIII-XLIII in FIG. 41.

FIG. 44 is a plan view showing the memory cell array of the resistance change memory.

FIG. 45 is a cross-sectional view seen along line XLV-XLV in FIG. 44.

FIG. 46 is a cross-sectional view seen along line XLVI-XLVI in FIG. 44.

FIG. 47 is a plan view showing the memory cell array of the resistance change memory.

FIG. 48 is a cross-sectional view seen along line XLVIII-XLVIII in FIG. 47.

FIG. 49 is a cross-sectional view seen along line XLIX-XLIX in FIG. 47.

FIG. 50 is a plan view showing the memory cell array of the resistance change memory.

FIG. 51 is a cross-sectional view seen along line LI-LI in FIG. 50.

FIG. 52 is a cross-sectional view seen along line LII-LII in FIG. 50.

FIG. 53 is a plan view showing the memory cell array of the resistance change memory.

FIG. 54 is a cross-sectional view seen along line LIV-LIV in FIG. 53.

FIG. 55 is a cross-sectional view seen along line LV-LV in FIG. 53.

FIG. 56 is a plan view showing the memory cell array of the resistance change memory.

FIG. 57 is a cross-sectional view seen along line LVII-LVII in FIG. 56.

FIG. 58 is a cross-sectional view seen along line LVIII-LVIII in FIG. 56.

FIG. 59 is a plan view showing the memory cell array of the resistance change memory.

FIG. 60 is a cross-sectional view seen along line LX-LX in FIG. 59.

FIG. 61 is a cross-sectional view seen along line LXI-LXI in FIG. 59.

FIG. 62 is a block diagram showing main portions of an MRAM.

FIG. 63 is a block diagram showing a hierarchical bit line structure.

FIG. 64 is a circuit diagram showing a layout of sub-arrays.

FIG. 65A and FIG. 65B are cross-sectional views showing a device structure as an applicable example.

FIG. 66 is a circuit diagram showing an equivalent circuit of the device structure shown in FIG. 65A and FIG. 65B.

FIG. 67 is a block diagram showing an example of a nonvolatile cache system.

FIG. 68 and FIG. 69 are cross-sectional views showing examples of a magnetoresistive element.

### DETAILED DESCRIPTION

In general, according to one embodiment, a resistance change memory comprises: a first conductive region; first and second semiconductor pillars on the first conductive region; a first word line including a first portion surrounding a side surface of the first pillar, a second portion surrounding a side surface of the second pillar, and a third portion connecting between the first and second portions, the first and second portions being physically separated from one another; a first resistance change element connected to an upper portion of the first semiconductor pillar; a second resistance change element connected to an upper portion of the second semiconductor pillar; a first bit line connected to the first resistance change element; and a second bit line connected to the second resistance change element.

### 1. DEVICE STRUCTURE

First, a device structure will be explained.

In the following embodiments, a memory cell comprises a resistance change element and a cell transistor and the cell transistor is a vertical transistor.

The resistance change element indicates an element capable of storing data by resistance change. For example, the resistance change element comprises a magnetoresistive element, a phase change element, etc. The resistance change element stores, for example, n-bit data (where n is a natural integer greater than or equal to 1). When the resistance change element stores the n-bit data, the resistance change element has a 2n resistance value.

In addition, the vertical transistor is, for example, a surrounding gate transistor (SGT) which comprises a gate surrounding a side surface of a semiconductor pillar. The SGT in a small plain size can obtain a high driving force since a current path is perpendicular to the surface of the semiconductor substrate and a channel width is defined by a perimeter of the semiconductor pillar.

### (1) First Embodiment

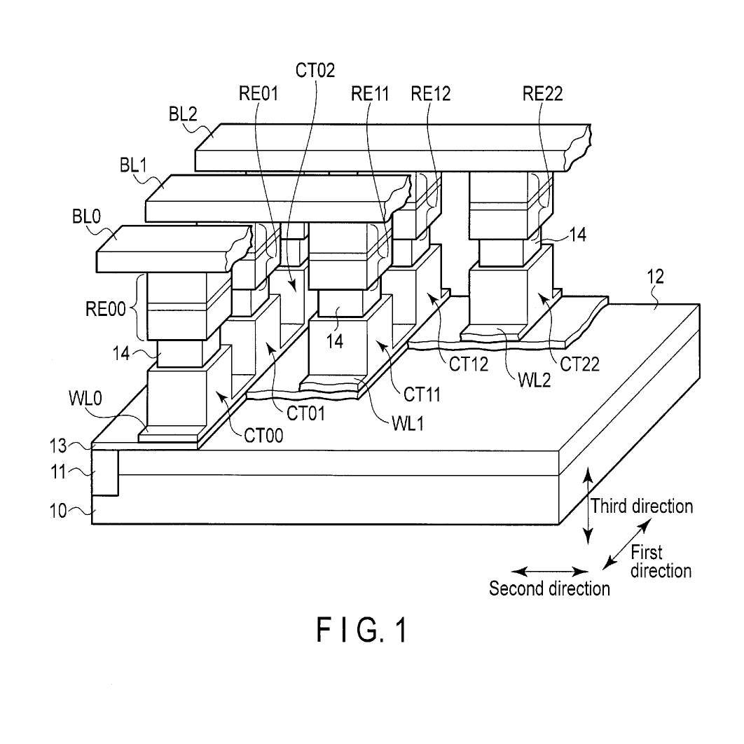

FIG. 1 to FIG. 7 show a first embodiment of the device structure.

FIG. 1 is a bird's eye view of a memory cell array of a resistance change memory. In FIG. 1, the device structure is broken and omitted in part to enable the structure of the memory cell array to be easily understood.

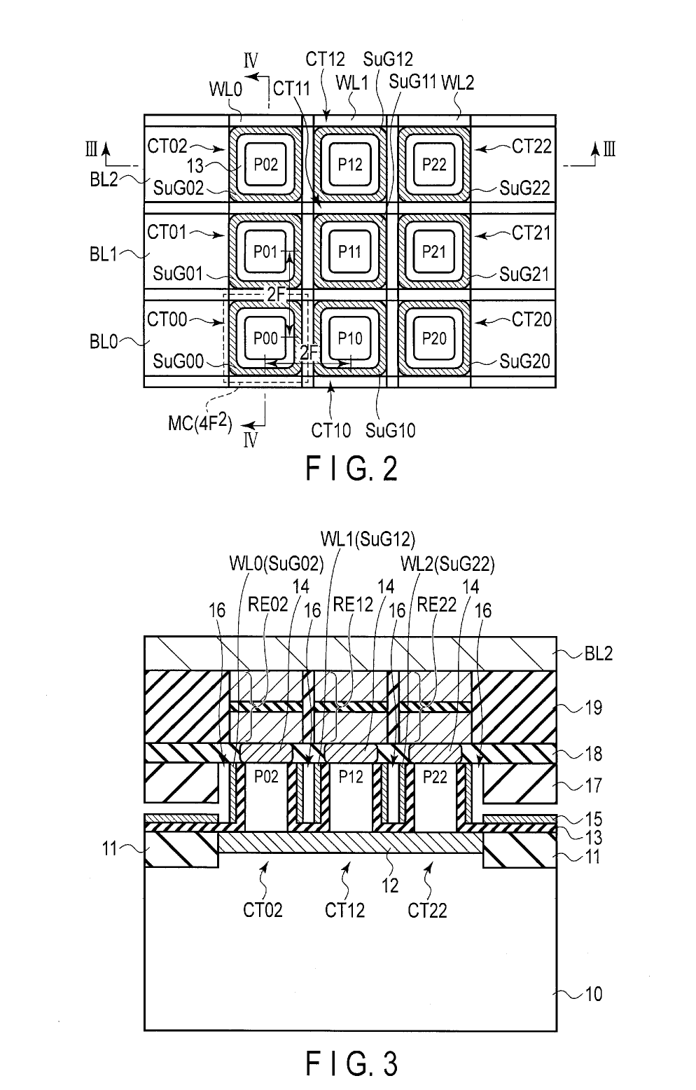

FIG. 2 is a plan view of the memory cell array of the resistance change memory. FIG. 3 is a cross-sectional view seen along line of FIG. 2.

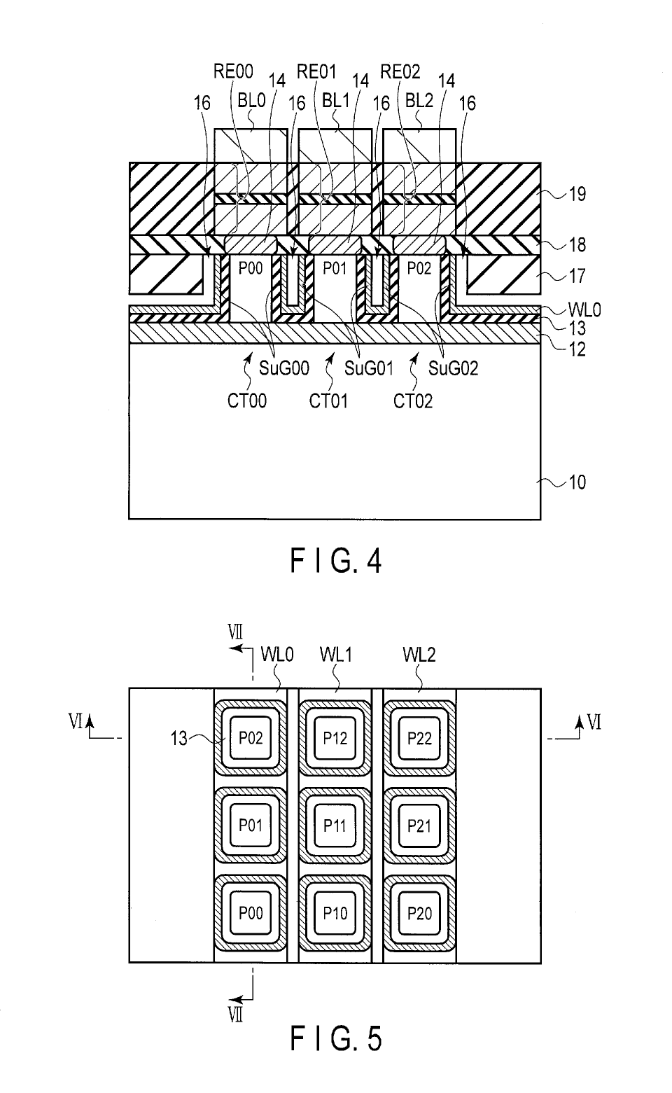

FIG. 4 is a cross-sectional view seen along line IV-IV line of FIG. 2.

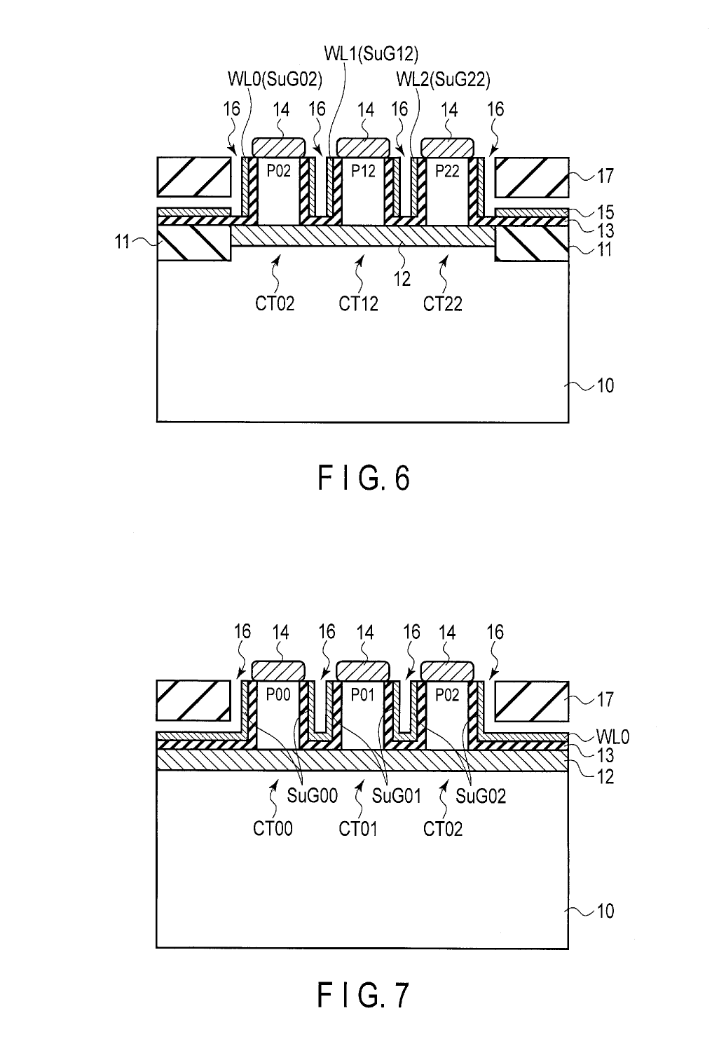

In FIG. 5, elements upper than the cell transistor in the resistance change memory of FIG. 2 are omitted to make the structure of the cell transistor easily understood. FIG. 6 is a cross-sectional view seen along line VI-VI of FIG. 5, and FIG. 7 is a cross-sectional view seen along line VII-VII of FIG. 5.

The structure of the first embodiment will be explained with reference to these figures.

A semiconductor substrate 10 is formed of, for example, single crystal silicon. An element isolation insulating layer 11 is formed of, for example, shallow trench isolation (STI) and disposed in the semiconductor substrate 11. A conductive region 12 is disposed in, for example, the semiconductor substrate 10 surrounded by the element isolation insulating layer 11. The conductive region 12 is, for example, an impurity region in the semiconductor substrate 10.

The conductive region 12 should, desirably, be formed in a plate shape to lower the resistance. However, the shape is not limited to this, but the conductive region 12 may be formed in a linear shape.

A plurality of semiconductor pillars P00, P01, P02, P10, P11, P12, P20, P21, and P22 are disposed on the conductive region 12. Semiconductor pillars P00, P01, P02, P10, P11, P12, P20, P21, and P22 are formed by, for example, patterning the semiconductor substrate 10. In this case, the plurality of semiconductor pillars P00, P01, P02, P10, P11, P12, P20, P21, and P22 contain the same material as the semiconductor substrate 10, for example, single crystal silicon.

The plurality of semiconductor pillars P00, P01, P02, P10, P11, P12, P20, P21, and P22 function as channels of cell transistors (field effect transistors) CT00, CT01, CT02, CT10, CT11, CT12, CT20, CT21 and CT22. In cell transistors CT00, CT01, CT02, CT10, CT11, CT12, CT20, CT21 and CT22, current paths are perpendicular to the surface of the semiconductor substrate 10, and channel widths are defined by perimeters of semiconductor pillars P00, P01, P02, P10, P11, P12, P20, P21, and P22.

In the present embodiment, each of the plurality of semiconductor pillars P00, P01, P02, P10, P11, P12, P20, P21, and P22 is shaped in a quadrangular prism, but the shape is not limited to this. For example, each of the plurality of semiconductor pillars P00, P01, P02, P10, P11, P12, P20, P21, and P22 may be in a columnar shape.

A plurality of word lines (gates) WL0, WL1 and WL2 are extended in a first direction parallel to a surface of the semiconductor substrate 10, and arranged in a second direction which is parallel to the surface of the semiconductor substrate 10 and intersects the first direction. A plurality of word lines WL0, WL1 and WL2 are formed of metal, for example, Ti, TiN, etc. A gate insulating layer 13, for example, a silicon oxide layer is disposed between the plurality of word lines WL0, WL1 and WL2 and the plurality of semiconductor pillars P00, P01, P02, P10, P11, P12, P20, P21, and P22. The gate insulating layer 13 may be formed of an insulating material (high-k material) having a specific dielectric constant greater than the silicon oxide layer, for example, CeO₂, Y₂O₃, Al₂O₃, Ta₂O₅, ZrO₂, HfO₂, TiO₂, SrTiO₃, BaSrTiO₃, etc.

Word line WL0 is disposed commonly to the plurality of semiconductor pillars P00, P01, and P02 disposed in the first direction. Word line WL0 includes, for example, a first portion (gate) SuG00 surrounding side surfaces of semiconductor pillar P00, a second portion (gate) SuG01 surrounding side surfaces of semiconductor pillar P01, and a third portion (interconnect) making connection between first portion SuG00 and second portion SuG01.

The thickness of each of first portion SuG00 and second portion SuG01 in the first direction and the second direction parallel to the surface of the semiconductor substrate 10 is substantially equal to the thickness of the third portion in a third direction perpendicular to the surface of the semiconductor substrate 10, i.e., a direction in which the plurality of semiconductor pillars P00, P01, and P02 are extended. This means that word line WL0 is a thin film and does not fill space in semiconductor pillars P00, P01, and P02.

First portion SuG00 and second portion SuG01 of word line WL0 are therefore physically separated from each other. The space between first portion SuG00 and second portion SuG01 of word line WL0 should, desirably, be an air gap 16 for reduction of an inter-gate capacity, but is not limited to this. For example, the space between first portion SuG00 and second portion SuG01 of word line WL0 may be an air gap in part or filled with a silicon oxide layer or an insulating layer having a specific dielectric constant lower than the silicon oxide layer.

The space in word lines WL1 and WL2 may be formed similarly.

For example, word line WL1 is disposed commonly to the plurality of semiconductor pillars P10, P11, and P12 disposed in the first direction. Word line WL1 includes, for example, a first portion (gate) SuG10 surrounding side surfaces of semiconductor pillar P10, a second portion (gate) SuG11 surrounding side surfaces of semiconductor pillar P11, and a third portion (interconnect) making connection between first portion SuG10 and second portion SuG11.

The thickness of each of first portion SuG10 and second portion SuG11 in the first direction and the second direction parallel to the surface of the semiconductor substrate 10 is substantially equal to the thickness of the third portion in a third direction perpendicular to the surface of the semiconductor substrate 10, i.e., a direction in which the plurality of semiconductor pillars P10, P11, and P12 are extended. This means that word line WL1 is a thin film and does not fill space in semiconductor pillars P10, P11, and P12.

First portion SuG10 and second portion SuG11 of word line WL1 are therefore physically separated from each other. The space between first portion SuG10 and second portion SuG11 of word line WL1 should, desirably, be the air gap 16 for reduction of an inter-gate capacity, but is not limited to this.

The feature that the plurality of word lines WL0, WL1 and WL2 are thin films indicates an effect that when the plurality of word lines WL0, WL1 and WL2 are patterned, i.e., when a word line material (metal) in the plurality of semiconductor pillars P00, P01, P02, P10, P11, P12, P20, P21, and P22 in the second direction is removed, accuracy in patterning word lines WL0, WL1 and WL2 is enhanced.

In addition, in FIG. 3 to FIG. 6, 15 denotes a word line material remaining on the element isolation insulating layer 11 after patterning the plurality of word lines WL0, WL1 and WL2.

A plurality of electrodes 14 are disposed on the plurality of semiconductor pillars P00, P01, P02, P10, P11, P12, P20, P21, and P22, respectively. The plurality of electrodes 14 are, for example, epitaxial layers formed by epitaxial growth and contain a conductive semiconductor (for example, conductive silicon) including impurities.

The plurality of electrodes 14 are disposed for the purpose of reducing an aspect ratio of the plurality of semiconductor pillars P00, P01, P02, P10, P11, P12, P20, P21, and P22, preventing electric short circuit between the plurality of word lines WL0, WL1 and WL2 and a plurality of resistance change elements RE00, RE01, RE02, RE10, RE11, RE12, RE20, RE21 and RE22, etc.

Upper ends of the first and second portions of the plurality of word lines WL0, WL1 and WL2 are therefore positioned to be lower than upper ends of the plurality of electrodes 14.

Interlayer insulating layers (for example, silicon oxide layers) 17 and 18 are disposed between adjacent electrodes of the electrodes 14. However, the interlayer insulating layers 17 and 18 do not fill the air gaps 16 between adjacent semiconductor pillars of the plurality of semiconductor pillars P00, P01, P02, P10, P11, P12, P20, P21, and P22.

The plurality of resistance change elements RE00, RE01, RE02, RE10, RE11, RE12, RE20, RE21 and RE22 are disposed directly above the plurality of electrodes 14, respectively. In other words, the plurality of resistance change elements RE00, RE01, RE02, RE10, RE11, RE12, RE20, RE21 and RE22 are laid out to overlap the plurality of cell transistors CT00, CT01, 0102, CT10, CT11, CT12, CT20, CT21 and CT22, respectively.

As a plain size of a memory cell, i.e., a cell size in a surface parallel to the surface of the semiconductor substrate 10, 4F² can be thereby implemented. F indicates a future size, which is a minimum processing dimension (line width or space width) of photolithographic line and space.

In the embodiments, each of a pitch in the layout of the plurality of semiconductor pillars P00, P01, P02, P10, P11, P12, P20, P21, and P22 and a pitch in the layout of the plurality of resistance change elements RE00, RE01, RE02, RE10, RE11, RE12, RE20, RE21 and RE22, is set at 2F.

It should be noted that each of the plurality of resistance change elements RE00, RE01, RE02, RE10, RE11, RE12, RE20, RE21 and RE22 is, for example, a magnetoresistive element.

The plurality of bit lines BL0, BL1 and BL2 are extended in the second direction and disposed side by side in the first direction. The plurality of bit lines BL0, BL1 and BL2 are formed of metal, for example, TiN, Ti, W, Ta, etc.

Bit line BL0 is connected commonly to the plurality of resistance change elements RE00, RE10 and RE20 disposed in the second direction, bit line BL1 is connected commonly to the plurality of resistance change elements RE01, RE11 and RE21 disposed in the second direction, and bit line BL2 is connected commonly to the plurality of resistance change elements RE02, RE12 and RE22 disposed in the second direction.

An interlayer insulating layer (for example, silicon oxide layer) 19 is disposed between adjacent elements of the plurality of resistance change elements RE00, RE01, RE02, RE10, RE11, RE12, RE20, RE21 and RE22.

According to the first embodiment, the gate (word line) of the vertical transistor (for example, SGT) serving as a cell transistor is a thin film, and does not fill the space between adjacent pillars of the plurality of semiconductor pillars (channels) in a direction in which the gate is extended. Thus, even if the cell transistors are miniaturized, gate patterning can be easily executed and small cell transistors of high driving power and high reliability can be implemented.

### (2) Second Embodiment

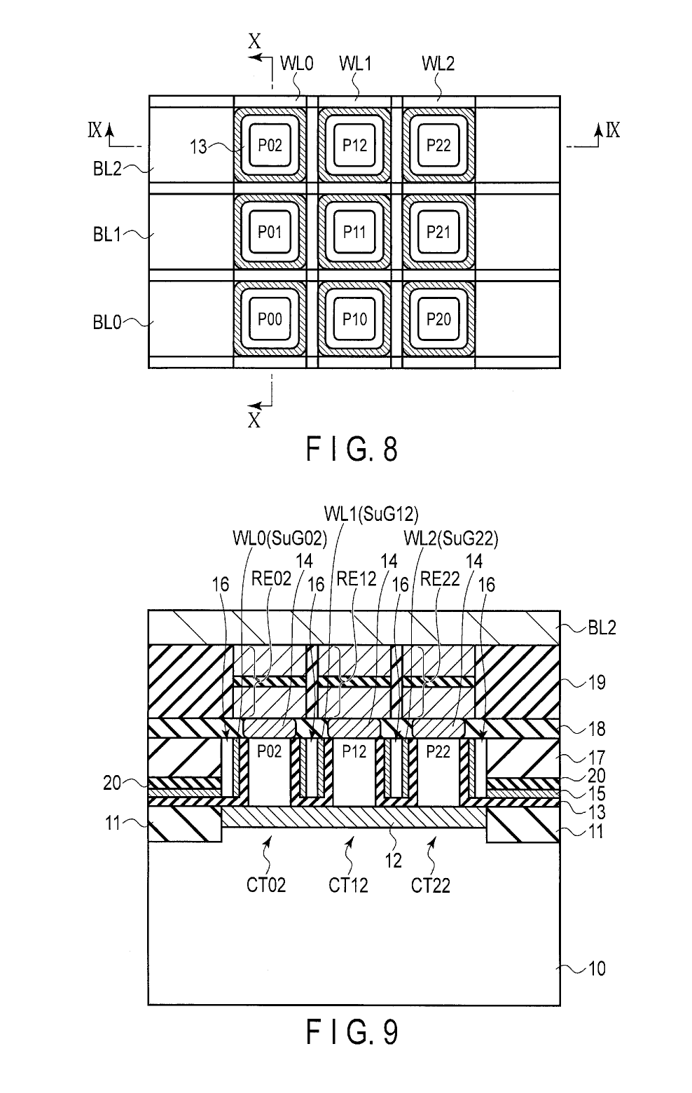

FIG. 8 to FIG. 10 show a second embodiment of the device structure.

FIG. 8 is a plan view of the memory cell array of the resistance change memory. FIG. 9 is a cross-sectional view seen along line IX-IX of FIG. 8.

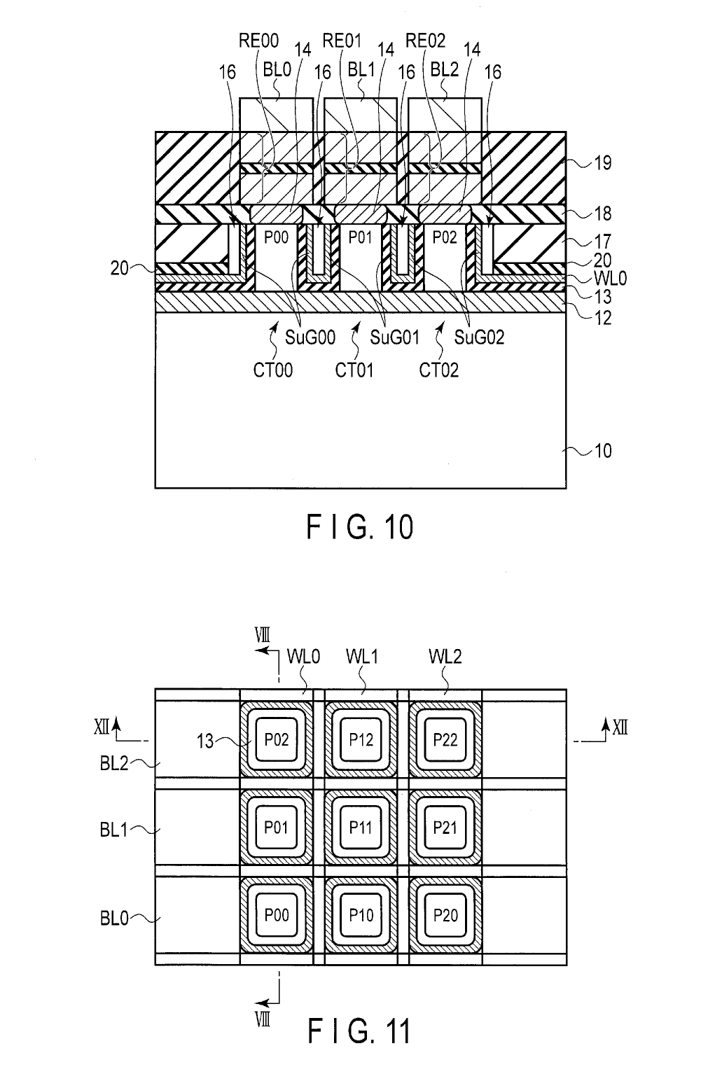

FIG. 10 is a cross-sectional view seen along line X-X of FIG. 8.

FIG. 8 to FIG. 10 correspond to FIG. 2 to FIG. 4, respectively.

The structure of the second embodiment will be explained with reference to these views.

The second embodiment is a modified embodiment of the first embodiment. The second embodiment is different from the first embodiment with respect to a feature that the air gaps of the first embodiment are filled in part with an insulating layer 20. The other features are the same as those of the first embodiment and denoted by similar reference numbers and symbols, and their detailed explanations are omitted.

The insulating layer (for example, silicon nitride layer) 20 is disposed on, for example, the plurality of word lines WL0, WL1 and WL2 and the remaining word line material 15. However, the insulating layer 20 does not fill space between adjacent semiconductor pillars of the plurality of semiconductor pillars P00, P01, P02, P10, P11, P12, P20, P21, and P22. The space between adjacent semiconductor pillars of the plurality of semiconductor pillars P00, P01, P02, P10, P11, P12, P20, P21, and P22 is, for example, the air gap 16.

In the second embodiment, too, the gate (word line) of the vertical transistor (for example, SGT) serving as a cell transistor is a thin film, and does not fill the space between adjacent pillars of the plurality of semiconductor pillars (channels) in a direction in which the gate is extended. Thus, even if the cell transistors are miniaturized, gate patterning can be easily executed and small cell transistors of high driving power and high reliability can be implemented.

### (3) Third Embodiment

FIG. 11 to FIG. 13 show a third embodiment of the device structure.

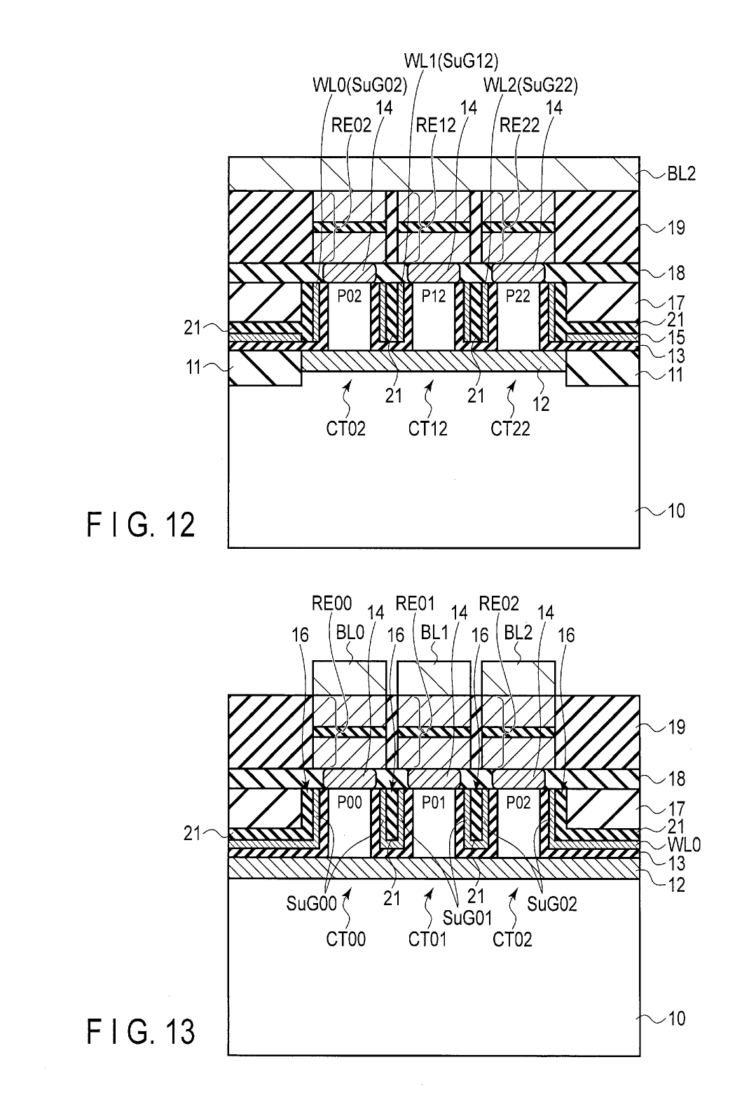

FIG. 11 is a plan view of the memory cell array of the resistance change memory. FIG. 12 is a cross-sectional view seen along line XII-XII of FIG. 11. FIG. 13 is a cross-sectional view seen along line XIII-XIII of FIG. 11.

FIG. 11 to FIG. 13 correspond to FIG. 2 to FIG. 4, respectively.

The structure of the third embodiment will be explained with reference to these views.

The third embodiment is also a modified embodiment of the first embodiment. The third embodiment is different from the first embodiment with respect to a feature that the air gaps of the first embodiment are filled with an insulating layer 21. The other features are the same as those of the first embodiment and denoted by similar reference numbers and symbols, and their detailed explanations are omitted.

The insulating layer 21 is disposed on, for example, the plurality of word lines WL0, WL1 and WL2 and the remaining word line material 15, and in the space between adjacent semiconductor pillars of the plurality of semiconductor pillars P00, P01, P02, P10, P11, P12, P20, P21, and P22. The insulating layer 21 should, preferably, be an insulating layer having a lower specific dielectric constant than silicon oxide to reduce parasitic capacitance in the plurality of word lines WL0, WL1 and WL2.

In the third embodiment, too, the gate (word line) of the vertical transistor (for example, SGT) serving as a cell transistor is a thin film, and does not fill the space between adjacent pillars of the plurality of semiconductor pillars (channels) in a direction in which the gate is extended. Thus, even if the cell transistors are miniaturized, gate patterning can be easily executed and small cell transistors of high driving power and high reliability can be implemented.

### (4) Fourth Embodiment

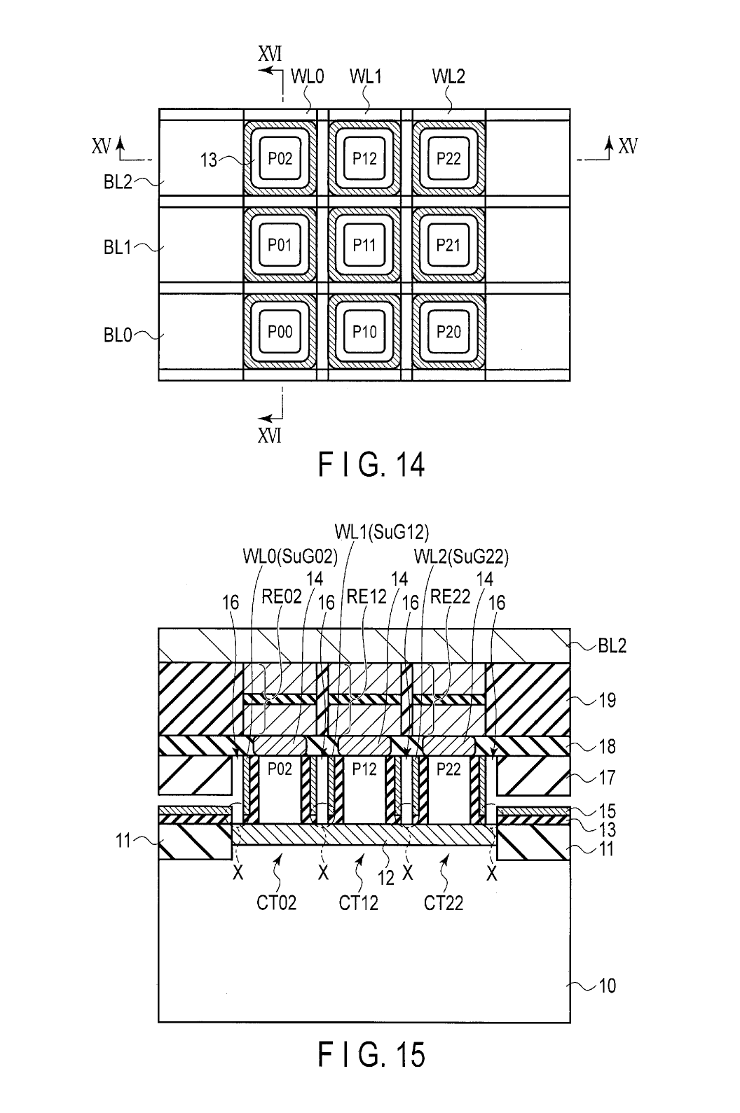

FIG. 14 to FIG. 16 show a fourth embodiment of the device structure.

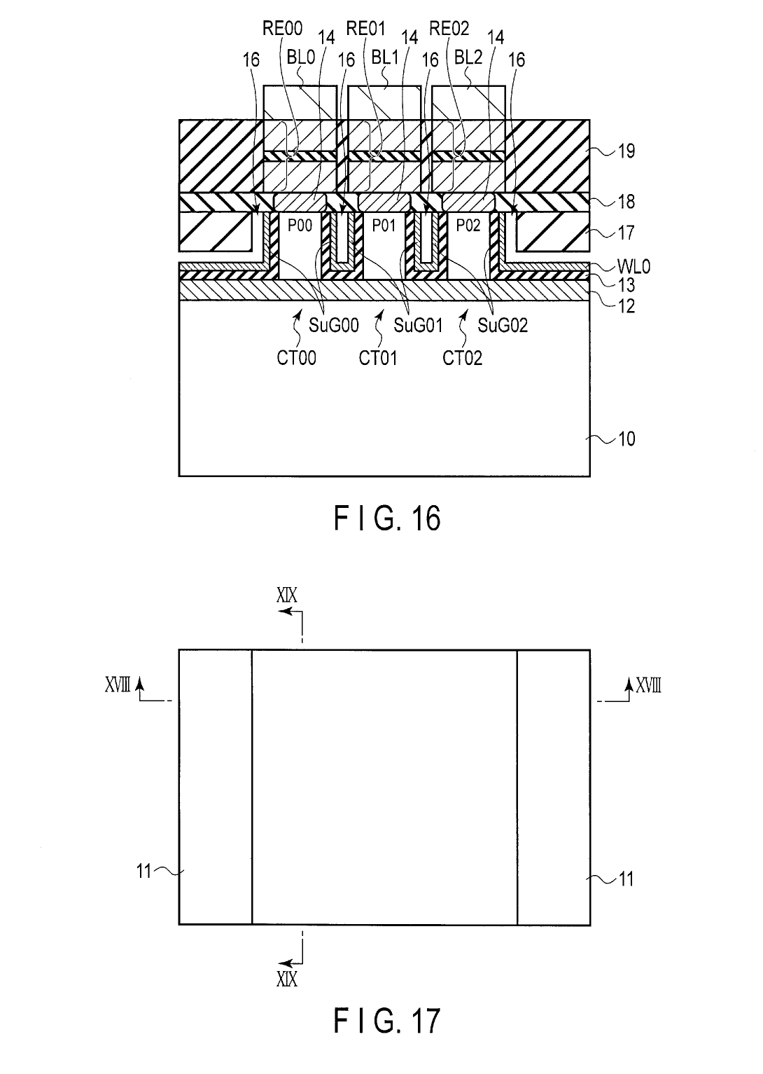

FIG. 14 is a plan view of the memory cell array of the resistance change memory. FIG. 15 is a cross-sectional view seen along line XV-XV of FIG. 14. FIG. 16 is a cross-sectional view seen along line XVI-XVI of FIG. 14.

FIG. 14 to FIG. 16 correspond to FIG. 2 to FIG. 4, respectively.

The structure of the fourth embodiment will be explained with reference to these figures.

The fourth embodiment is also a modified embodiment of the first embodiment. The fourth embodiment is different from the first embodiment with respect to a feature that the air gap reaches the conductive region 12. The other features are the same as those of the first embodiment and denoted by similar reference numbers and symbols, and their detailed explanations are omitted.

The air gaps 16 are disposed between adjacent semiconductor pillars of the plurality of semiconductor pillars P00, P01, P02, P10, P11, P12, P20, P21, and P22. The air gaps 16 are formed by, for example, selectively removing the insulating layer (silicon nitride, etc.) In this process, the gate insulating layer 13 is often removed in part (as represented by a broken-line area X). In this case, the air gaps 16 are extended up to the conductive region 12.

In the fourth embodiment, too, the gate (word line) of the vertical transistor (for example, SGT) serving as a cell transistor is a thin film, and does not fill the space between adjacent pillars of the plurality of semiconductor pillars (channels) in a direction in which the gate is extended. Thus, even if the cell transistors are miniaturized, gate patterning can be easily executed and small cell transistors of high driving power and high reliability can be implemented.

### 2. MANUFACTURING METHOD

A method of manufacturing the resistance change memory of the first to fourth embodiments will be explained.

In the process explained below, the same element as those explained in the first to fourth embodiments are denoted by similar reference numbers and symbols, to clarify correspondence of the device structure to the manufacturing method.

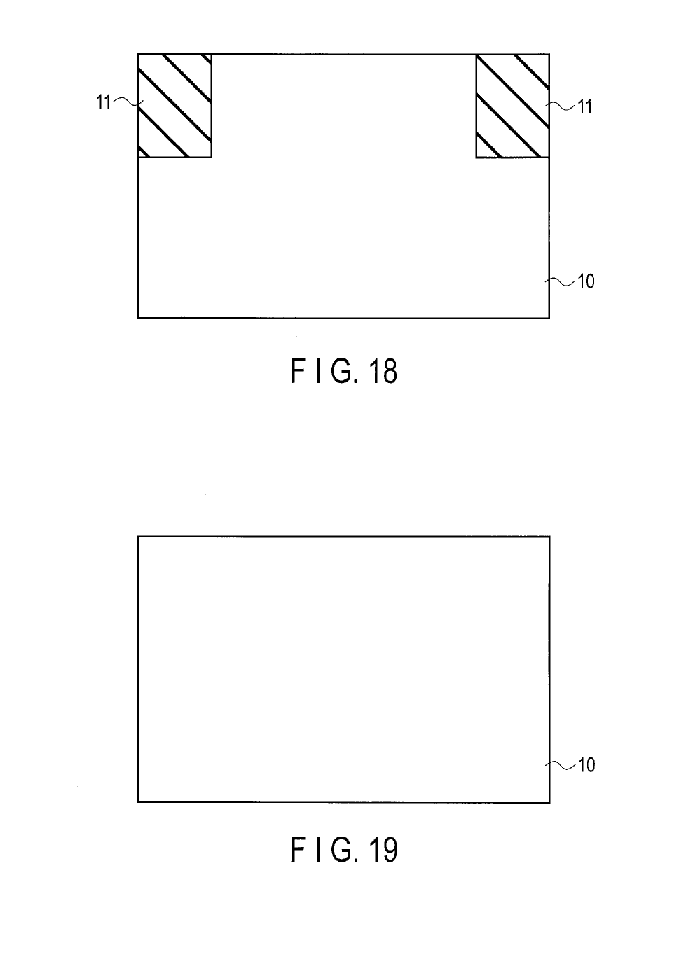

First, STI is formed in the semiconductor substrate 10 as the element isolation insulating layer as shown in FIG. 17 to FIG. 19.

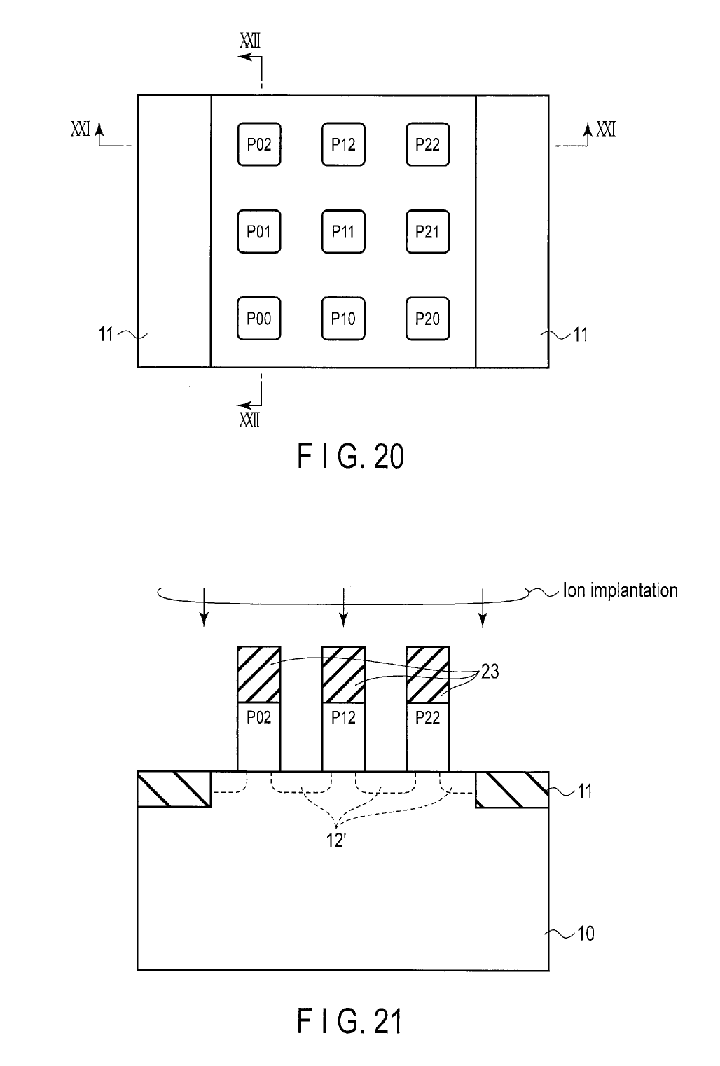

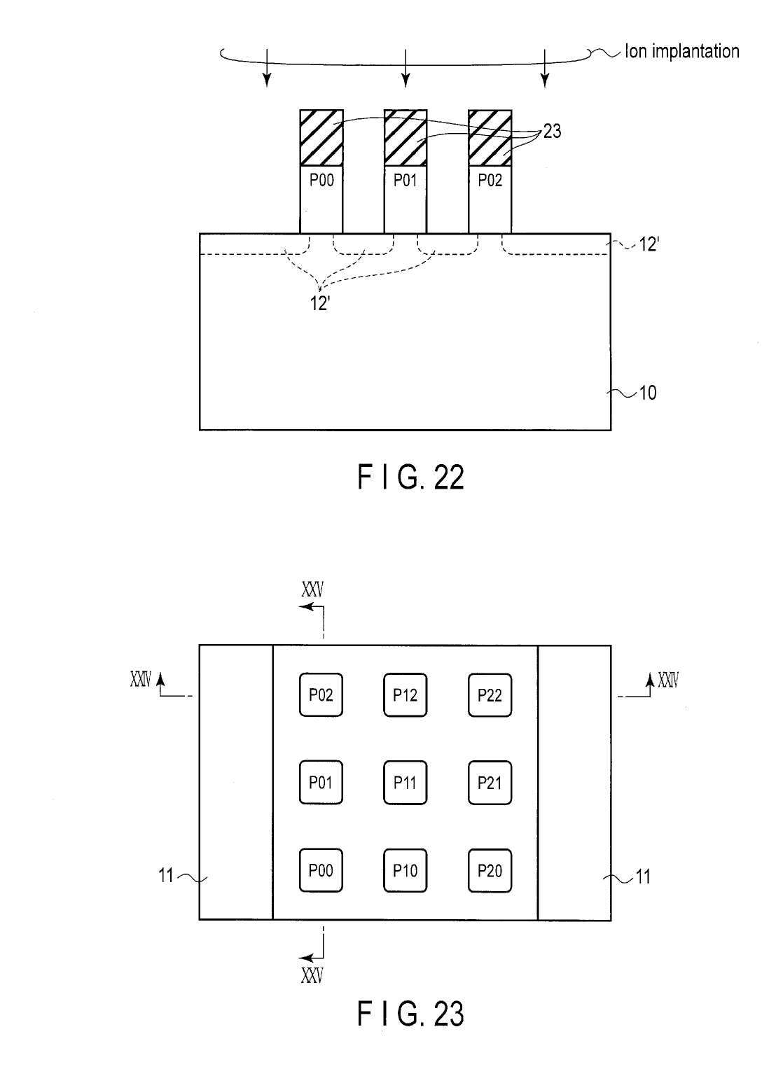

Next, an insulating layer (for example, a silicon oxide layer) 23 is formed on the semiconductor substrate 10, and the insulating layer 23 is patterned by photo-engraving process (PEP) and reactive ion etching (RIE), as shown in FIG. 20 to FIG. 22. After that, the plurality of semiconductor pillars P00, P01, P02, P10, P11, P12, P20, P21, and P22 are formed by etching the semiconductor substrate 10 by RIE using the insulating layer 23 as a mask.

The perimeter of each of the plurality of semiconductor pillars P00, P01, P02, P10, P11, P12, P20, P21, and P22 is defined as a channel width of the cell transistor, and the height of each of the semiconductor pillars is defined as a channel length of the cell transistor.

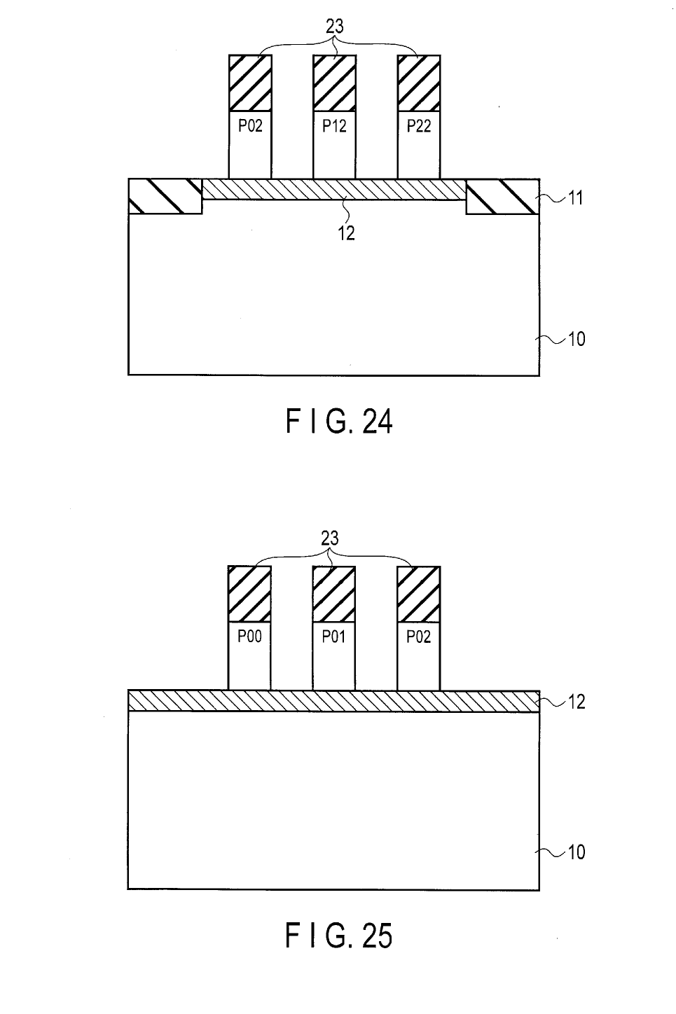

In addition, an impurity region 12′ is formed in the semiconductor substrate 10 by implanting impurities into the semiconductor substrate 10 by ion implantation using the insulating layer 23 as a mask. After that, when the impurities in the impurity region 12′ are activated by annealing, the conductive region 12 is formed in the semiconductor substrate 10 as shown in FIG. 23 to FIG. 25.

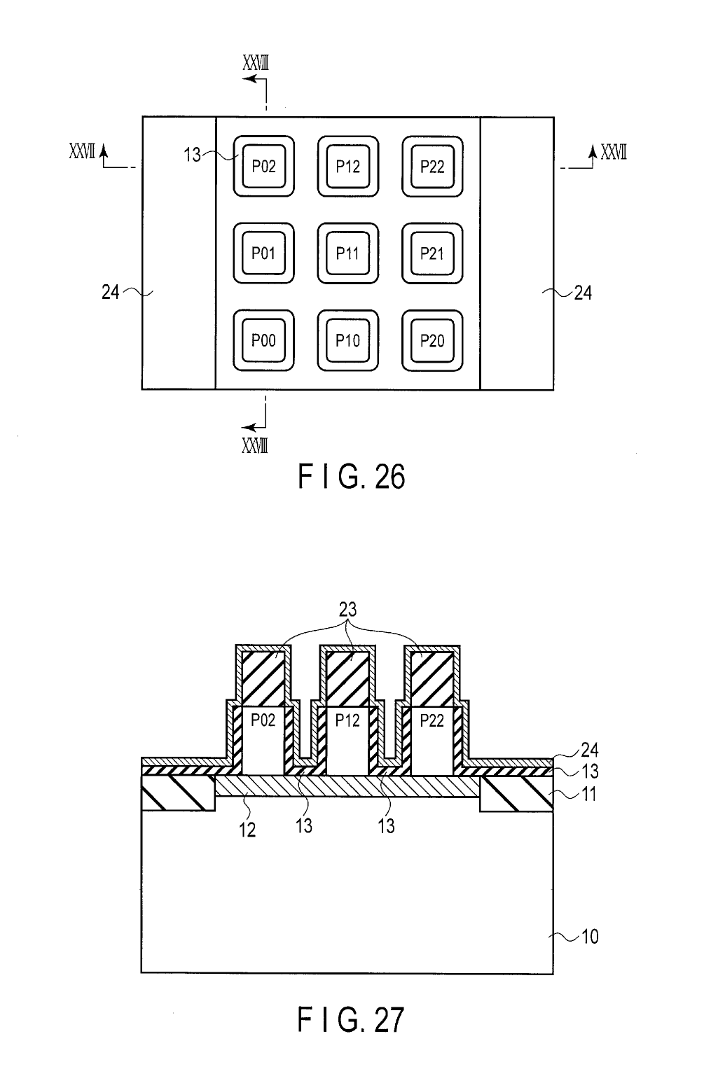

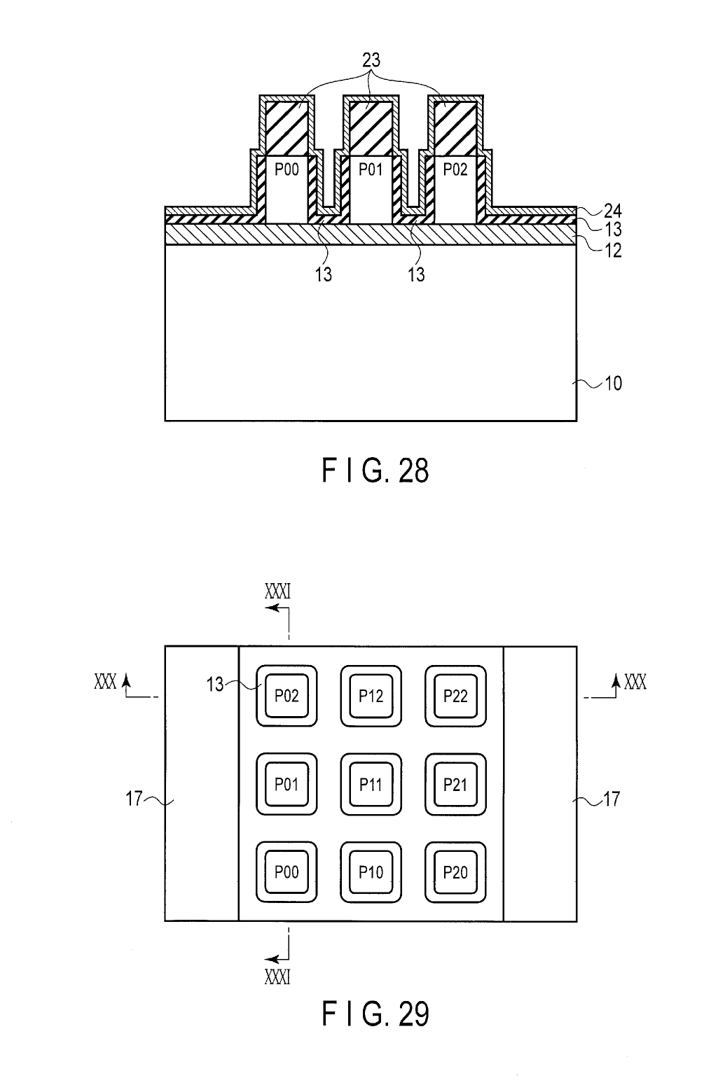

Next, a conductive layer (thin film) 24 which covers the plurality of semiconductor pillars P00, P01, P02, P10, P11, P12, P20, P21, and P22 and the insulating layer 23 is formed by, for example, atomic layer deposition (ALD), chemical vapor deposition (CVD), etc., as shown in FIG. 26 to FIG. 28. The conductive layer 24 is formed to be thinner than a half of the width of the space so as to fill no space between adjacent semiconductor pillars of the plurality of semiconductor pillars P00, P01, P02, P10, P11, P12, P20, P21, and P22. The thickness of the conductive layer 24 is set to be, for example, approximately (F/3). However, F indicates a future size.

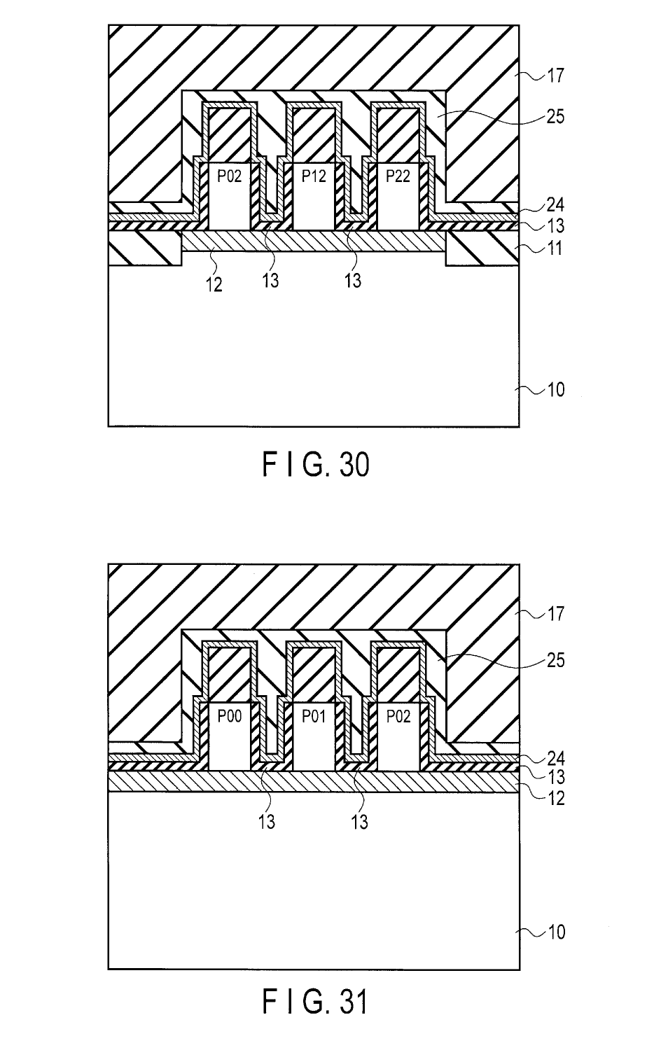

Next, an insulating layer (for example, silicon nitride layer) 25 is formed by, for example, ALD, to fill the space between adjacent semiconductor pillars of the plurality of semiconductor pillars P00, P01, P02, P10, P11, P12, P20, P21, and P22, as shown in FIG. 29 to FIG. 31. Subsequently, the insulating layer (for example, silicon oxide layer) 17 is formed on the insulating layer 25.

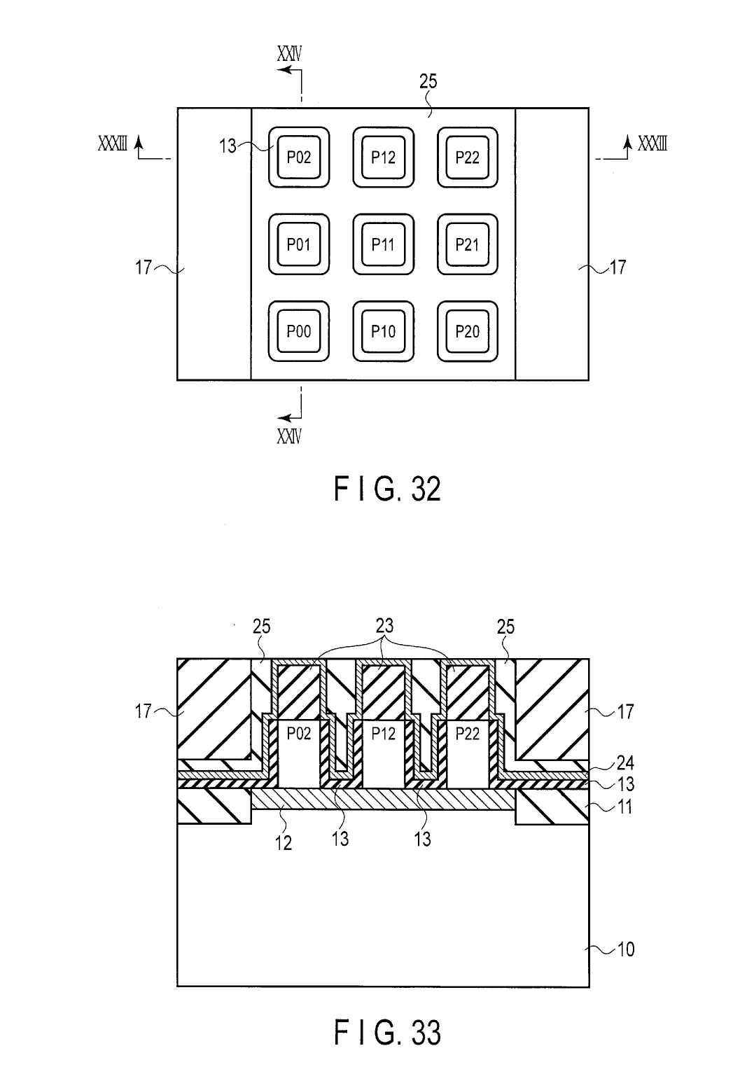

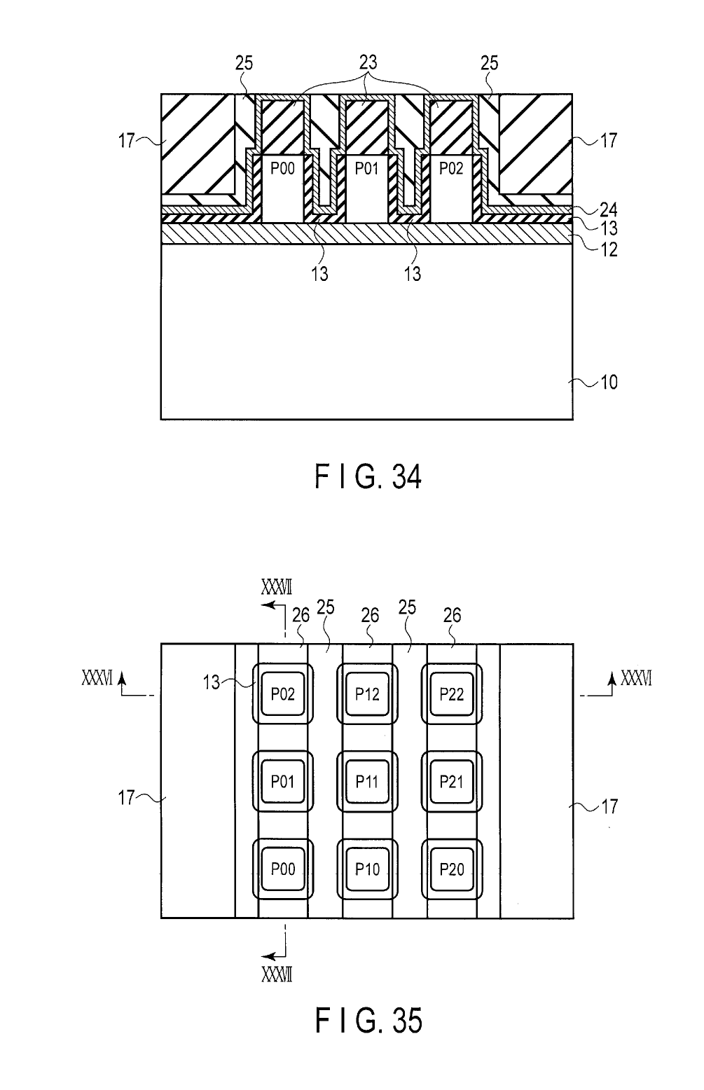

Next, the insulating layers 17 and 25 are polished by, for example, chemical mechanical polishing (CMP) until the conductive layer 24 is exposed in part, as shown in FIG. 32 to FIG. 34.

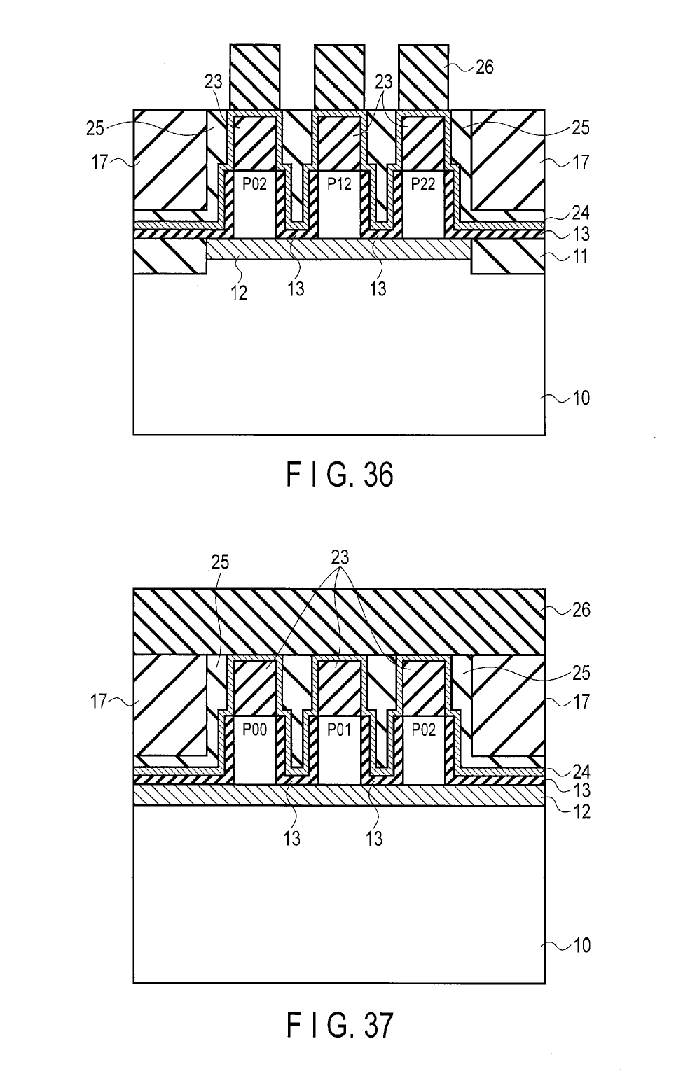

Next, an insulating layer (for example, a silicon oxide layer) 26 is formed on the insulating layers 17 and 25 and the conductive layer 24, and the insulating layer 26 is patterned by PEP and RIE, as shown in FIGS. 35 to 37. The patterned insulating layer 26 has a line and space pattern. After that, the insulating layer 25 is selectively etched by wet etching (for example, hot phosphoric acid etching using a heated phosphoric acid solution) using the insulating layer 26 as a mask.

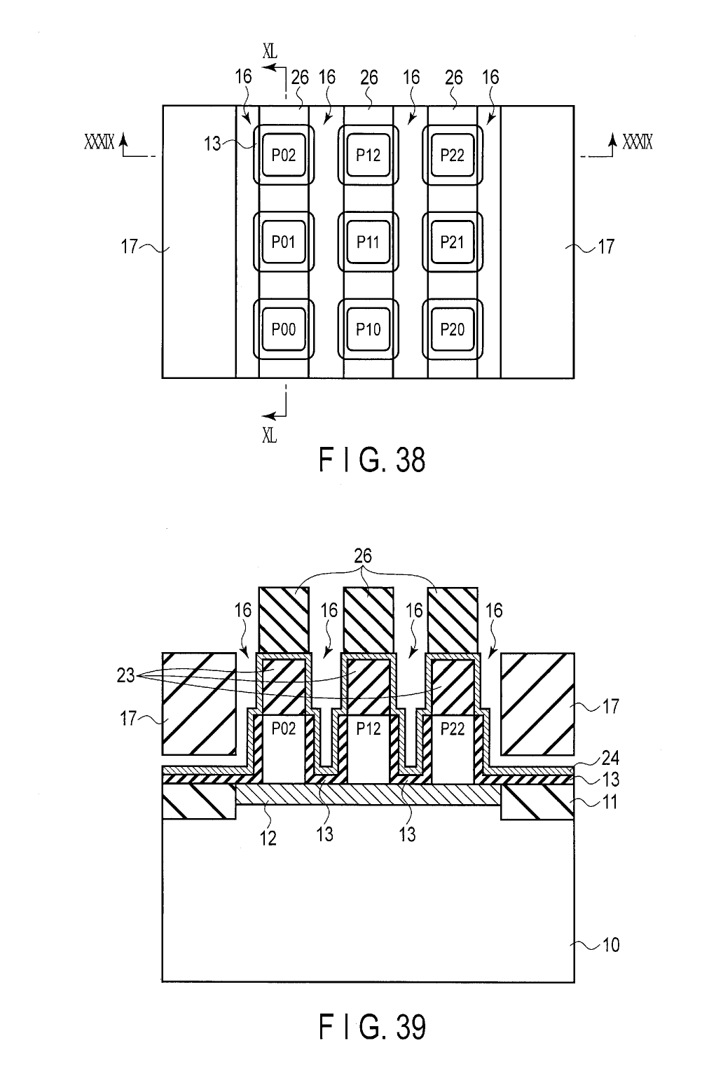

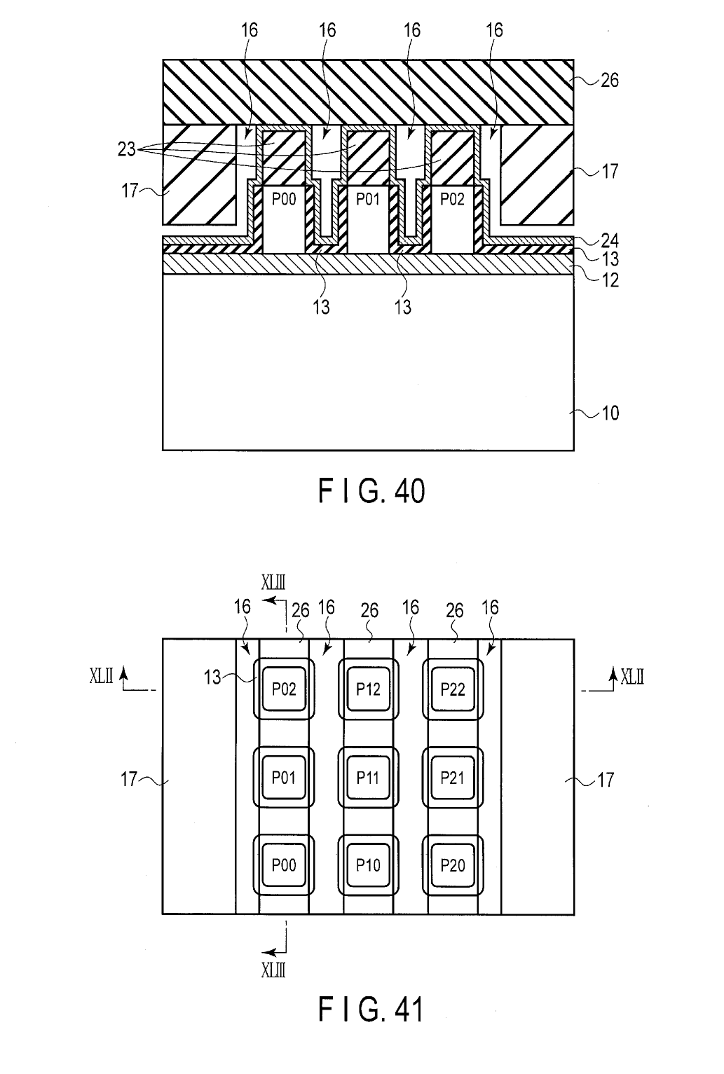

As a result, the space between adjacent semiconductor pillars of the plurality of semiconductor pillars P00, P01, P02, P10, P11, P12, P20, P21, and P22 becomes the air gap 16 as shown in FIG. 38 to FIG. 40.

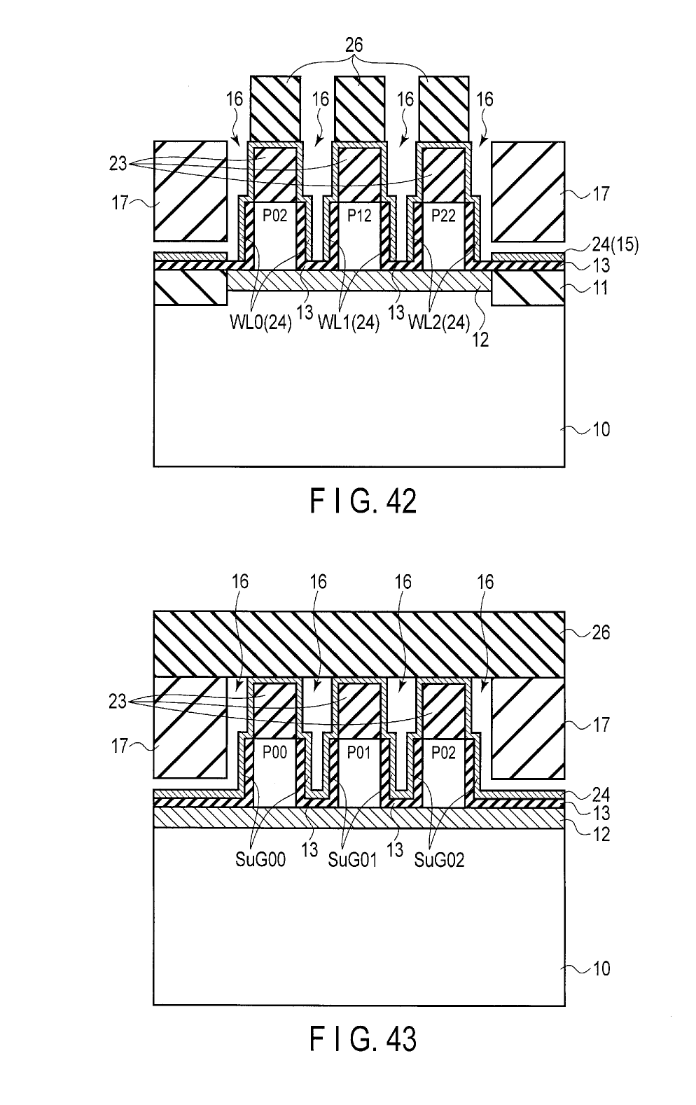

Next, the conductive layer 24 which is exposed in the air gaps 16 and which exists at portions uncovered with the insulating layer 17 or 26 is etched by, for example, RIE, as shown in FIG. 41 to FIG. 43. As a result, the conductive layer 24 is patterned in the line and space pattern to form the plurality of word lines WL0, WL1 and WL2.

The conductive layer 24 does not fill the space between adjacent semiconductor pillars of the plurality of semiconductor pillars P00, P01, P02, P10, P11, P12, P20, P21, and P22. In other words, the plurality of word lines WL0, WL1 and WL2 are formed by etching the thin conductive layer 24 disposed between adjacent semiconductor pillars of the plurality of semiconductor pillars P00, P01, P02, P10, P11, P12, P20, P21, and P22.

The plurality of word lines WL0, WL1 and WL2 can be therefore patterned with high accuracy.

After that, the insulating layer 26 is removed. However, the insulating layer 26 may not be removed but left as it is.

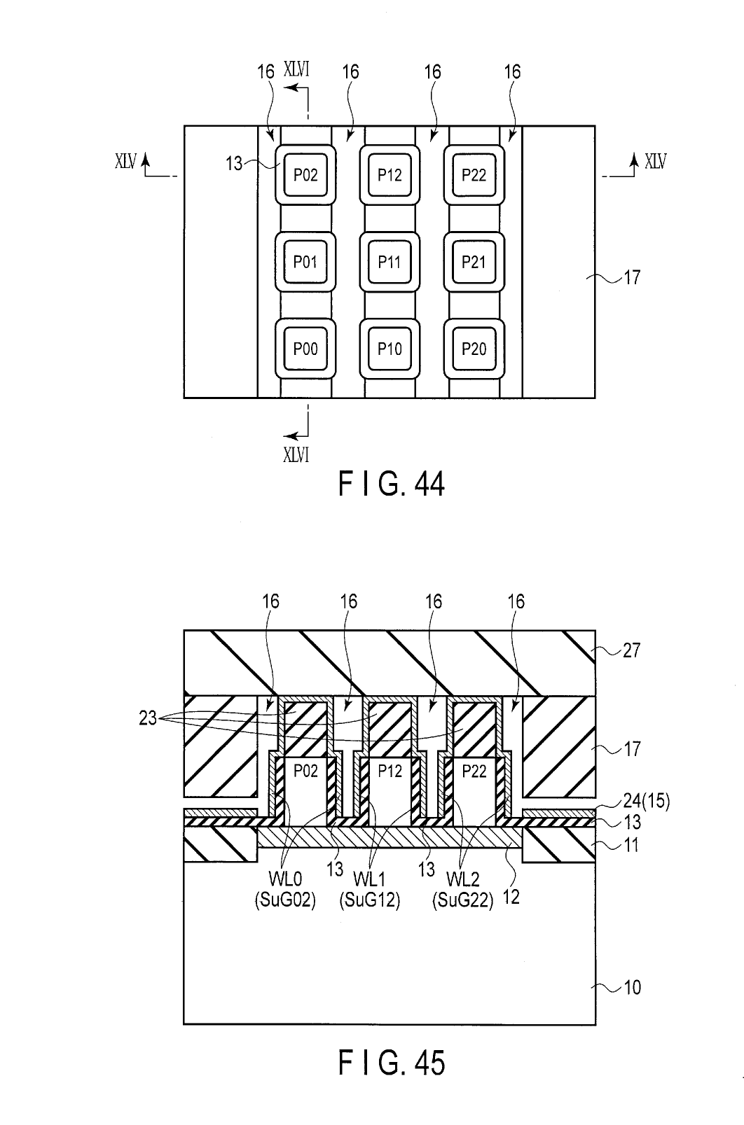

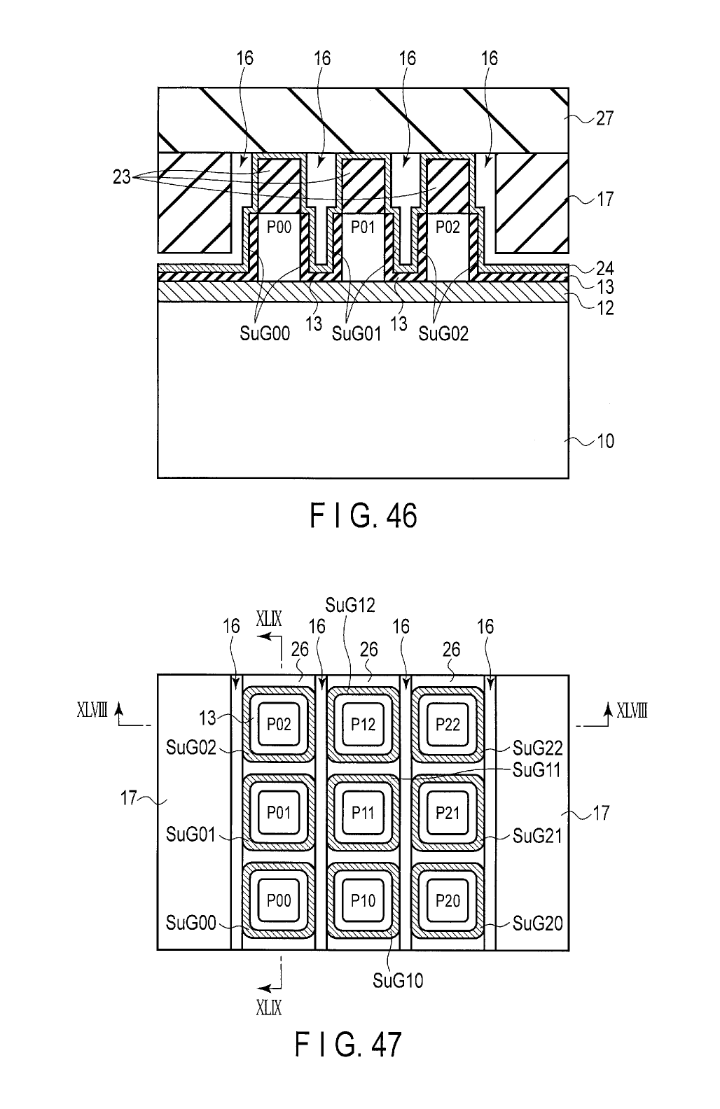

Next, an insulating layer (for example, a silicon oxide layer) 27 is formed on the insulating layer 17 and the plurality of word lines WL0, WL1 and WL2 by, for example, CVD as shown in FIG. 44 to FIG. 46. An insulating layer having poor coverage is used not to fill the space between adjacent semiconductor pillars of the plurality of semiconductor pillars P00, P01, P02, P10, P11, P12, P20, P21, and P22, as the insulating layer 27.

The space between adjacent semiconductor pillars of the plurality of semiconductor pillars P00, P01, P02, P10, P11, P12, P20, P21, and P22 remains as the air gap 16.

After that, the insulating layer 27 is polished until the plurality of word lines WL0, WL1 and WL2 are exposed by, for example, CMP. In other words, the insulating layer 27 is polished by using the plurality of word lines WL0, WL1 and WL2 as stopper layers. At this time, upper surfaces of the plurality of semiconductor pillars P00, P01, P02, P10, P11, P12, P20, P21, and P22 may be exposed by polishing the plurality of word lines WL0, WL1 and WL2 as the thin film.

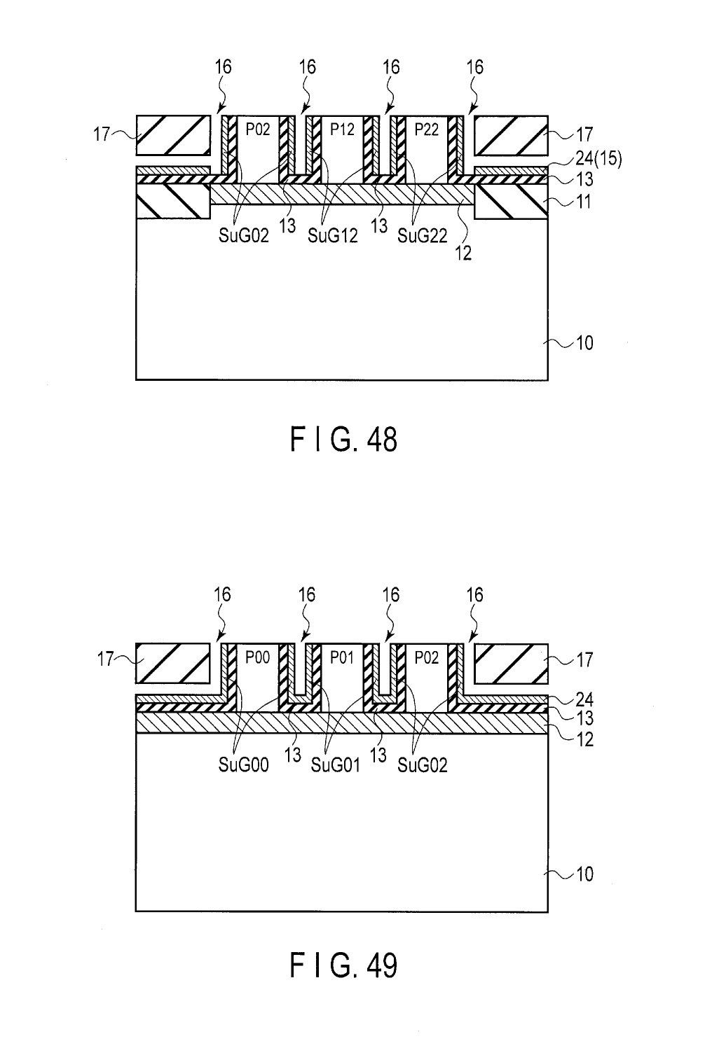

As a result, for example, the structure in which the upper surfaces of the plurality of semiconductor pillars P00, P01, P02, P10, P11, P12, P20, P21, and P22 are exposed can be obtained as shown in FIG. 47 to FIG. 49.

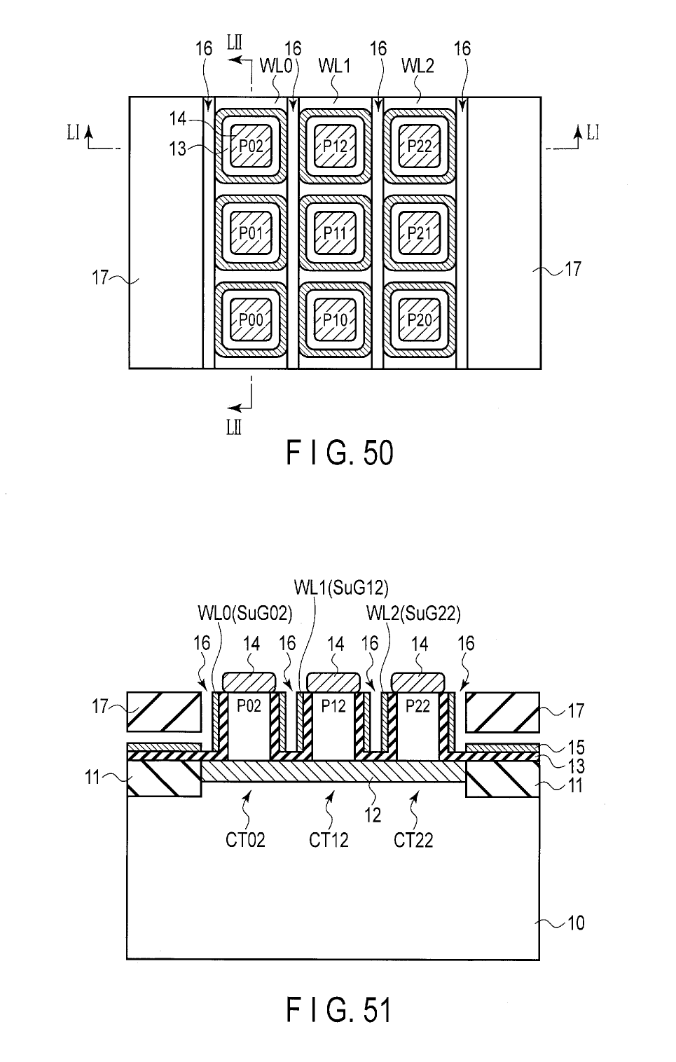

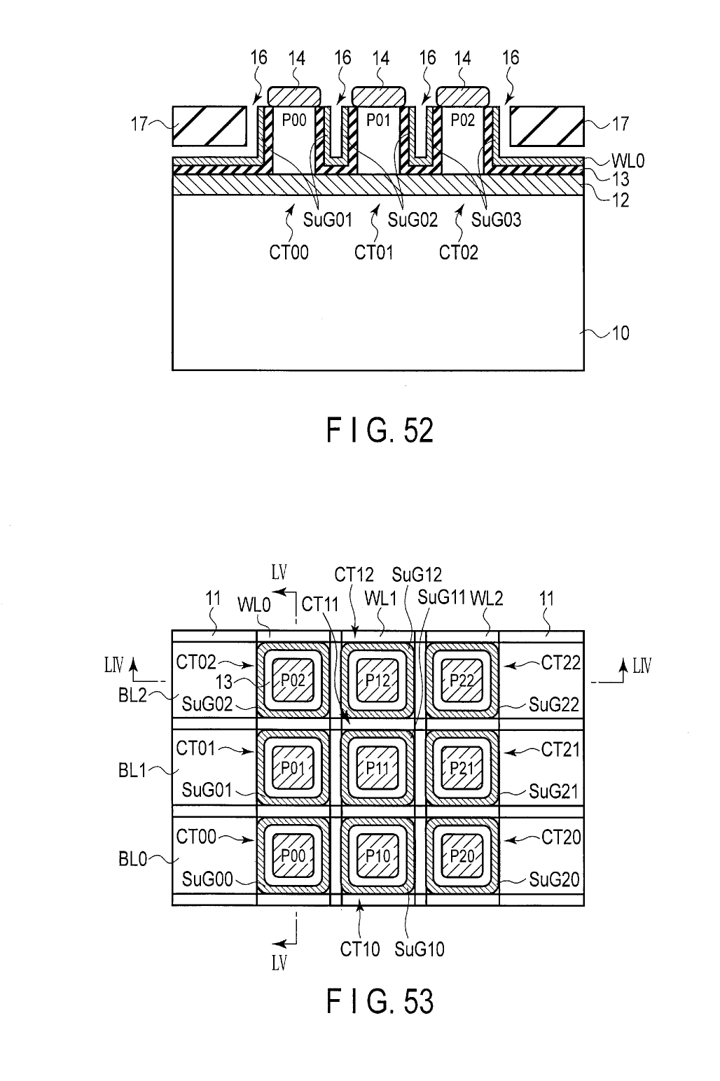

Next, the plurality of electrodes 14 serving as the epitaxial layer are formed on the plurality of semiconductor pillars P00, P01, P02, P10, P11, P12, P20, P21, and P22 by epitaxial growth, as shown in FIG. 50 to FIG. 52. According to the epitaxial growth, the plurality of electrodes 14 can be formed by self alignment with the plurality of semiconductor pillars P00, P01, P02, P10, P11, P12, P20, P21, and P22.

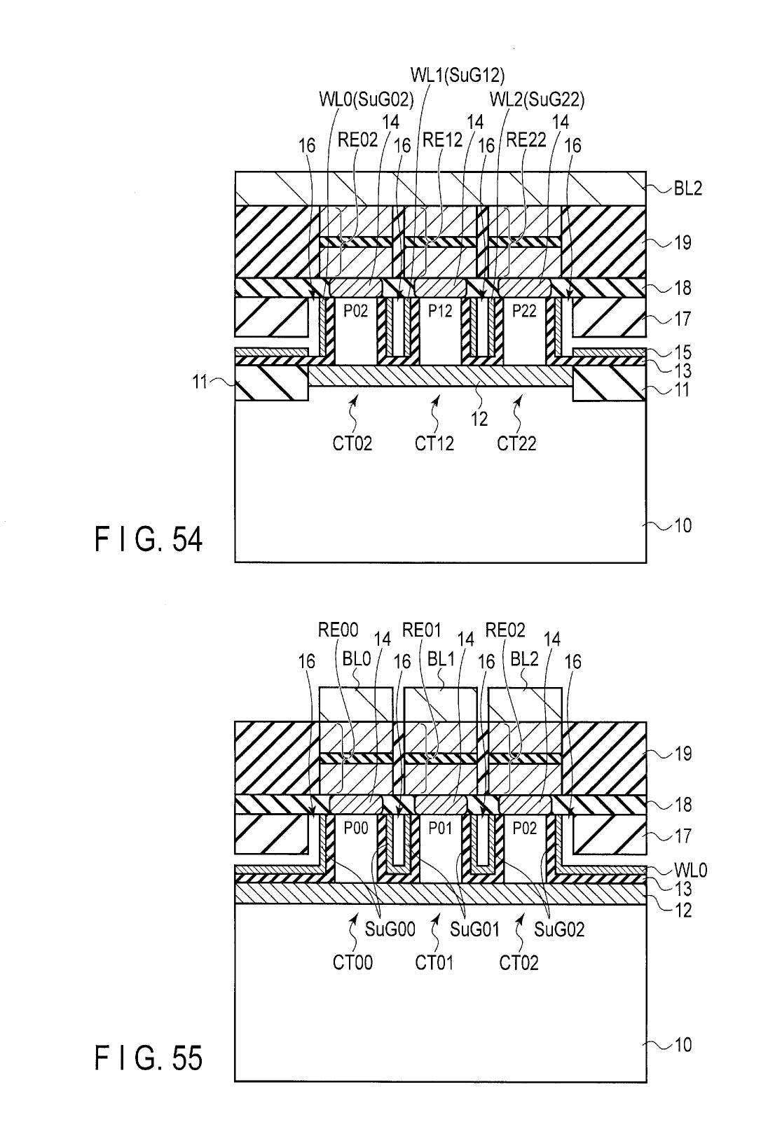

Finally, after an insulating layer 18 which covers the plurality of electrodes 14 is formed by CVD, the insulating layer 18 is polished by CMP until the top surfaces of the plurality of electrodes 14 are exposed, as shown in FIG. 53 to FIG. 55. The insulating layer 18 has a laminated structure of, for example, silicon nitride and silicon oxide.

In addition, the plurality of resistance change elements (for example, magnetoresistive elements) RE00, RE01, RE02, RE10, RE11, RE12, RE20, RE21 and RE22 are formed on the plurality of electrodes 14.

Furthermore, an insulating layer 19 is formed to fill space between adjacent magnetoresistive elements of the plurality of resistance change elements RE00, RE01, RE02, RE10, RE11, RE12, RE20, RE21 and RE22, and the plurality of bit lines BL0, BL1 and BL2 are formed.

At the formation of the plurality of electrodes 14 in the epitaxial growth, the following modification can be made to prevent electric short circuit from occurring at the plurality of electrodes 14.

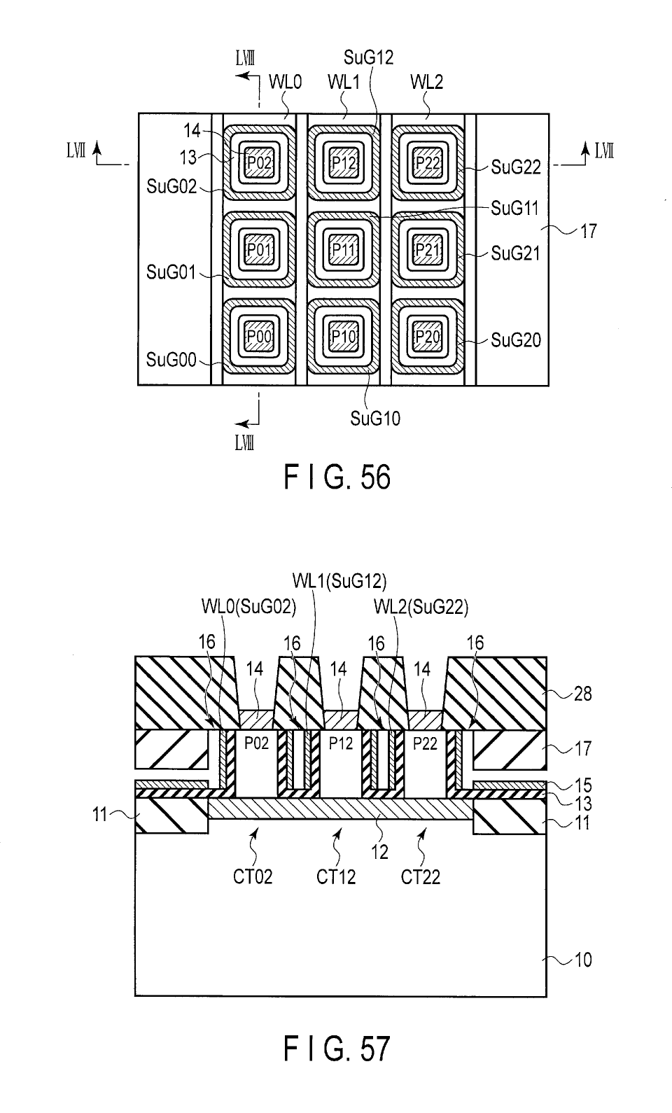

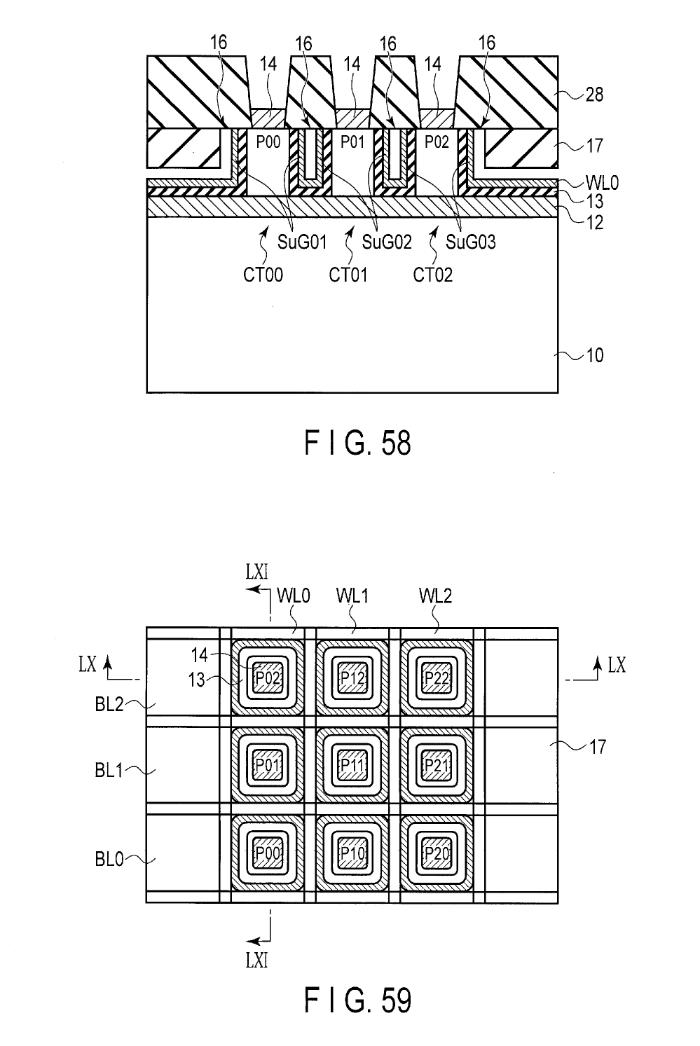

For example, an insulating layer (for example, silicon oxide layer) 28 which includes a plurality of opening portions on the plurality of semiconductor pillars P00, P01, P02, P10, P11, P12, P20, P21, and P22, respectively, is formed as shown in FIG. 56 to FIG. 58. After that, the plurality of electrodes 14 serving as the epitaxial layer are formed on the plurality of semiconductor pillars P00, P01, P02, P10, P11, P12, P20, P21, and P22 by epitaxial growth.

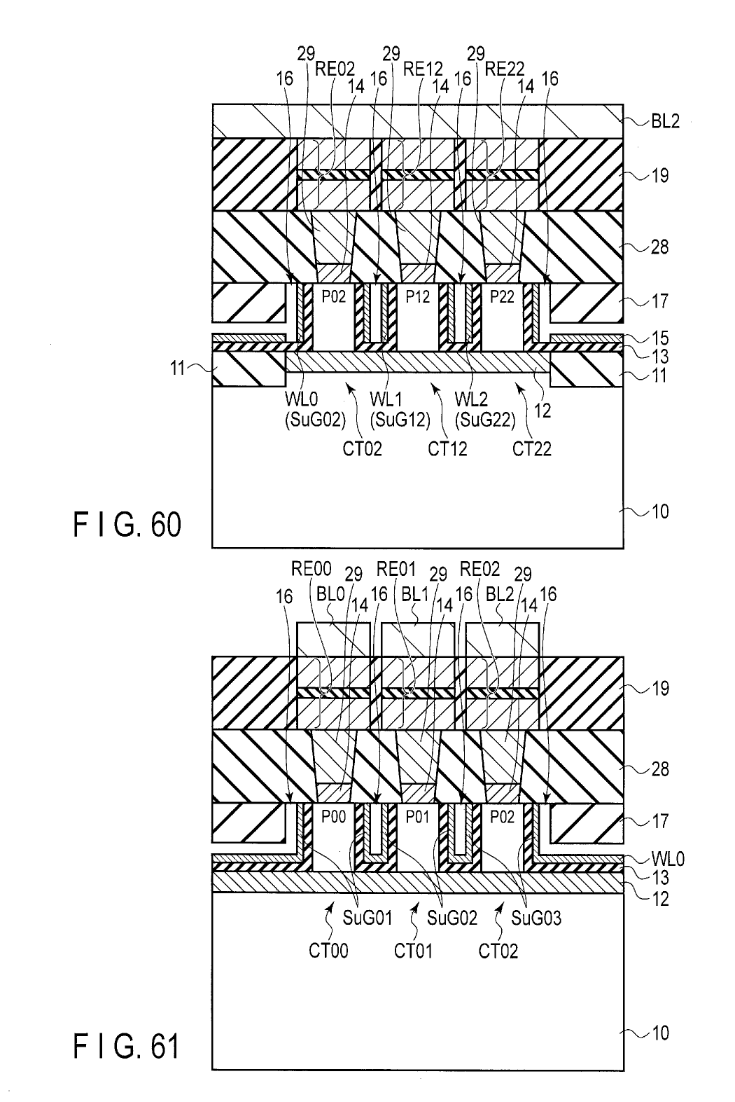

In addition, a plurality of plugs (conductive layer) 29 are formed to fill a plurality of opening portions of the insulating layer 28 as shown in FIG. 59 to FIG. 61. After that, the plurality of resistance change elements (for example, magnetoresistive elements) RE00, RE01, RE02, RE10, RE11, RE12, RE20, RE21 and RE22 are formed on the plurality of plugs 29.

According to the modified embodiment, the electric short circuit of the plurality of electrodes 14 caused by the epitaxial growth can be prevented.

The resistance change memory of each of the first to fourth embodiments can be formed in the above-explained manufacturing method.

### 3. MAGNETIC RANDOM ACCESS MEMORY

One type of high-speed, large-capacity next-generation nonvolatile memory is, for example, an MRAM which can store data in a magnetic tunnel junction (MTJ) element exhibiting a tunnel magneto resistance (TMR) effect.

The MRAM is capable of scaling the memory cell by an idea of spin implantation writing using the spin-momentum-transfer (SMT). In other words, if the MTJ element is miniaturized, the write current is reduced according to the spin implantation writing. In addition, thermal agitation tolerance of the MTJ element, i.e., the property of retention of the write data can be enhanced by using a perpendicular magnetization film in which an easy axis is perpendicular to the film surface for the MTJ element.

However, the MRAM has a problem that the cell transistor which supplies a write current necessary for magnetization inversion to the MTJ element cannot be sufficiently downsized.

Therefore, if the vertical transistor (for example, SGT) is applied to the MRAM as the cell transistor of the above-explained example, the MRAM can be put into practical use.

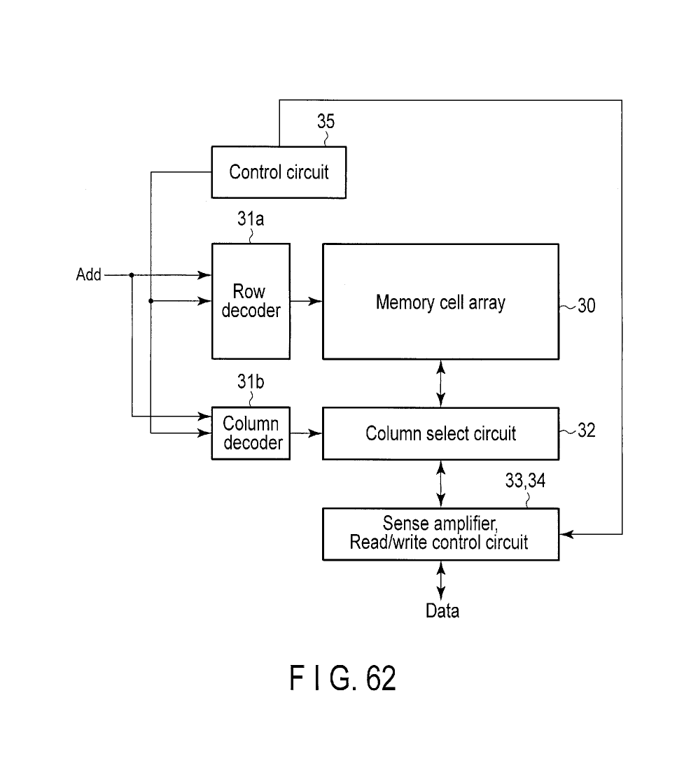

FIG. 62 shows main portions of the MRAM.

A memory cell array 30 comprises a plurality of memory cells. Each of a row decoder 31a and a column decoder 31b accesses at random one of the plurality of memory cells in the memory cell array 30, based on an address signal Add.

A column select circuit 32 plays a role of electrically connecting the memory cell array 30 and a sense amplifier 33 with each other, based on a signal from the column decoder 31b.

A read/write control circuit 34 supplies a read current to the selected memory cell in the memory cell array 30 at the read time. The sense amplifier 33 discriminates data stored in the selected memory cell by detecting the read current.

In addition, the read/write control circuit 34 writes data in the selected memory cell by supplying a write current to the selected memory cell in the memory cell array 30 at the write time.

A control circuit 35 controls operations of the row decoder 31a, the column decoder 31b, the sense amplifier 33, and the read/write control circuit 34.

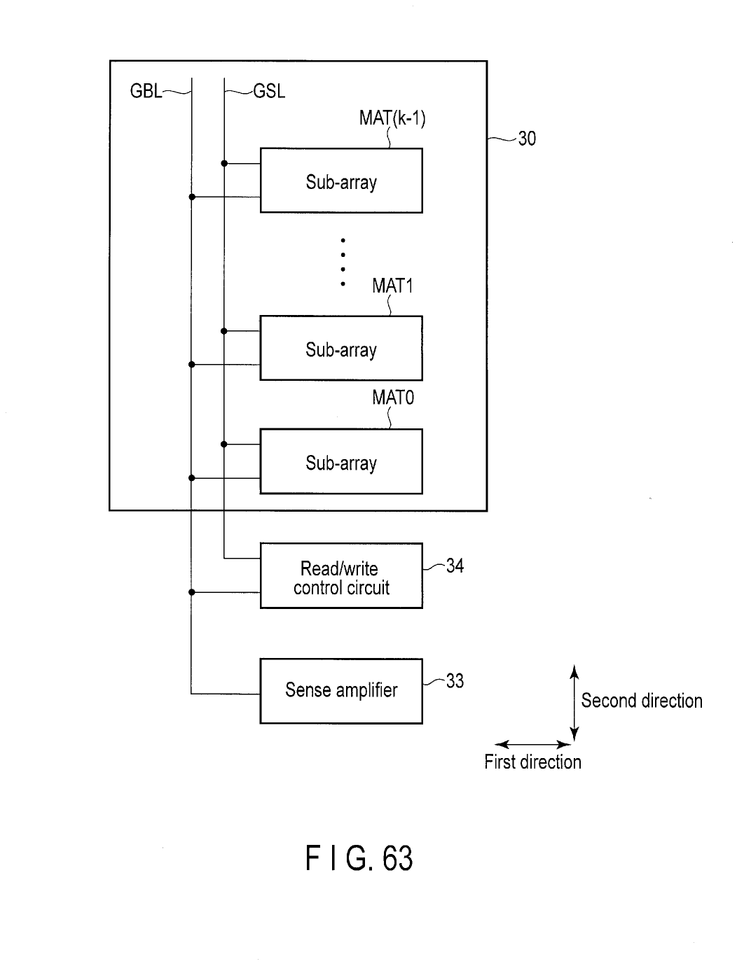

FIG. 63 shows a hierarchical bit line structure.

The memory cell array 30 comprises k sub-arrays (blocks) MAT0, MAT1, . . . MAT(k−1). The k sub-arrays MAT0, MAT1, MAT(k−1) are arranged side by side in, for example, the second direction. The k is a natural number greater than or equal to 2.

A global bit line GBL and a global source line GSL are extended in the second direction and connected to the k sub-arrays MAT0, MAT1, MAT(k−1).

The global bit line GBL is further connected to the sense amplifier 33 and the read/write control circuit 34. The global source line GSL is further connected to the read/write control circuit 34.

It should be noted that the memory cell array 30, the sense amplifier 33 and the read/write control circuit 34 correspond to the memory cell array 30, the sense amplifier 33 and the read/write control circuit 34, respectively.

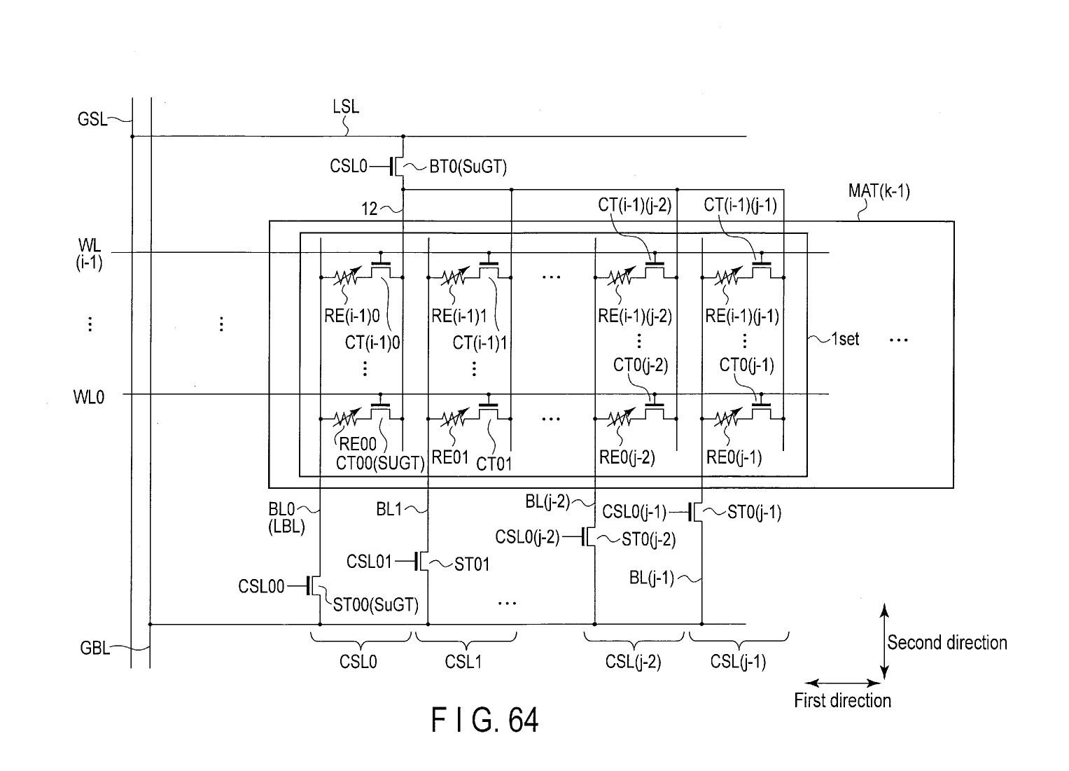

FIG. 64 shows an example of a layout of the sub-arrays.

Sub-array MAT(k−1) comprises a plurality of sets, for example, 256 sets. One set includes, for example, j columns COL0, . . . , COL(j−1) where j is a natural number greater than or equal to 2. j is, for example, 8. The global bit line GBL and the global source line GSL are disposed for each set.

The global bit line GBL is connected to select transistors ST00, ST0(j−1) serving as column select circuits. Select transistors ST00, ST0(j−1) can adopt vertical transistors (for example, SGT) as the cell transistors of the above-explained embodiments.

Select transistors ST00, ST0(j−1) connect the global bit line GBL to one of local bit lines BL0(LBL), BL(j−1)(LBL) in one of number j of columns COL0, . . . , COL(j−1), based on column select signals CSL00, CSL0(j−1).

The global source line GSL is connected to a block transistor BT0 serving as a block select circuit which selects one of sub-arrays (blocks) and one set of the selected sub-array, via a local source line LSL. The block transistor BT0 can adopt vertical transistors (for example, SGT) as the cell transistors of the above-explained embodiments.

The block transistor BT0 connects the global source line GSL to a conductive region (source impurity region of the cell transistor) in one set, based on block select signal OSLO.

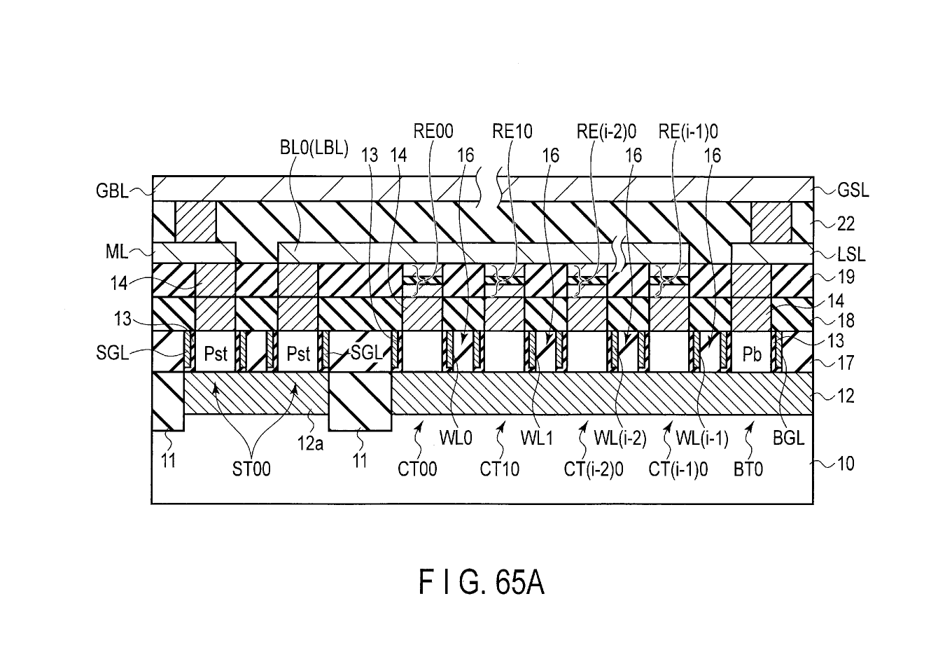

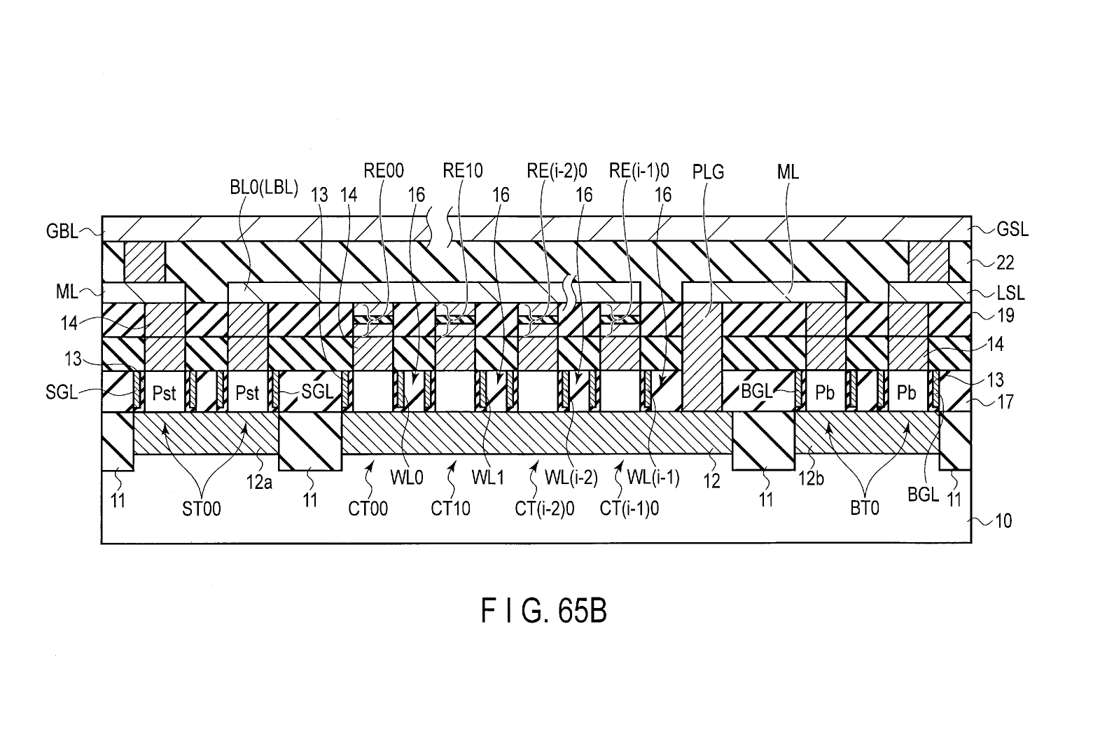

FIG. 65A and FIG. 65B show an example of a device structure implementing the hierarchical bit line structure shown in FIG. 64.

Cell transistors CT00, CT10, CT(i−2)0, and CT(i−1)0 and resistance change elements RE00, RE10, RE(i−2)0, and RE(i−1)0 have been explained in the first to fourth embodiments, and their explanations are omitted here.

The device structure of the present example has a characteristic that select transistor ST00 and the block transistor BT0 are vertical transistors (for example, SGT), respectively, similarly to cell transistors CT00, CT10, CT(i−2)0, and CT(i−1)0.

In the structure shown in FIG. 65A, select transistor ST00 comprises two vertical transistors. Each of the two vertical transistors comprises a conductive region 12a, a semiconductor pillar Pst on the conductive region 12a, and a select gate line SGL which surrounds side surfaces of semiconductor pillar Pst. Either of the two vertical transistors may be omitted.

The block transistor BT0 comprises a vertical transistor. The vertical transistor comprises a semiconductor pillar Pb on the conductive region 12, and a block gate line BGL which surrounds side surfaces of semiconductor pillar Pb.

In FIG. 65A, the same elements as those explained in the first to fourth embodiments are denoted by the same reference numbers and symbols. In FIG. 65A, 22 denotes an interlayer insulating layer and ML denotes an intermediate conductive layer.

In the structure shown in FIG. 65B, select transistor ST00 comprises two vertical transistors. Each of the two vertical transistors comprises a conductive region 12a, a semiconductor pillar Pst on the conductive region 12a, and a select gate line SGL which surrounds side surfaces of semiconductor pillar Pst. Either of the two vertical transistors may be omitted.

The block transistor BT0 also comprises two vertical transistors. Each of the two vertical transistors comprises a conductive region 12b, a semiconductor pillar Pb on the conductive region 12b, and a block gate line BGL which surrounds side surfaces of semiconductor pillar Pb. Either of the two vertical transistors may be omitted.

In FIG. 65B, too, the same elements as those explained in the first to fourth embodiments are denoted by the same reference numbers and symbols. In addition, in FIG. 65B, 22 denotes an interlayer insulating layer and ML denotes an intermediate conductive layer.

In FIG. 65A, select transistor ST00 is separated from cell transistors CT00, CT10, CT(i−2)0, and CT(i−1)0 by the element isolation insulating layer 11, and the block transistor BT0 and cell transistors CT00, CT10, CT(i−2)0, and CT(i−1)0 are disposed in the same element region (active area).

In contrast, in FIG. 65B, both select transistor ST00 and the block transistor BT0 are separated from cell transistors CT00, CT10, CT(i−2)0, and CT(i−1)0 by the element isolation insulating layer 11.

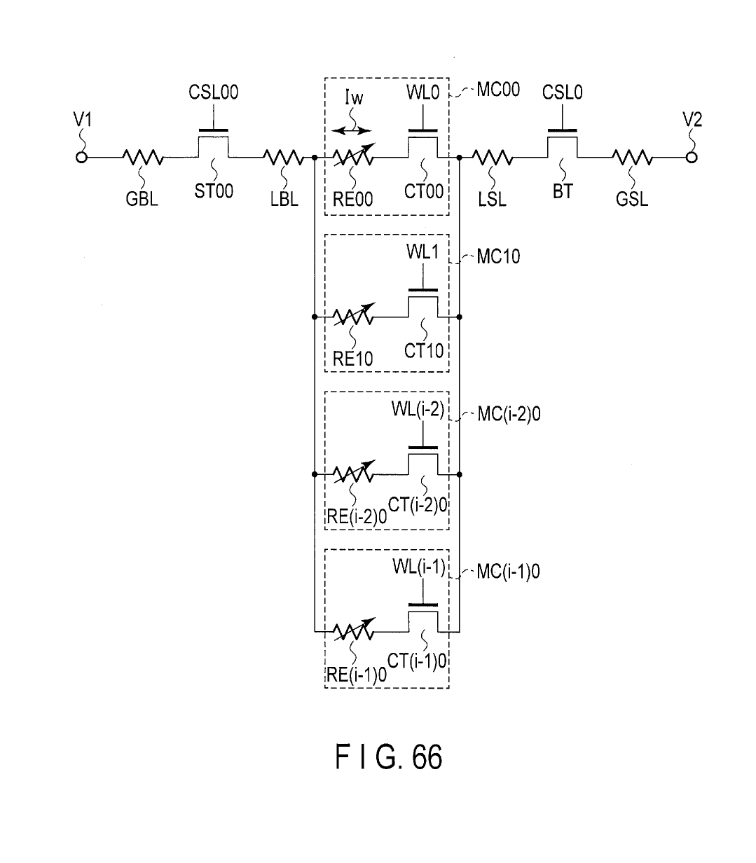

FIG. 66 shows an equivalent circuit of the device structure shown in FIG. 65A and FIG. 65B.

Writing will be explained.

For example, when data is written to resistance change element RE00 in memory cell MC00, both column select signal CSL00 and block select signal CSL0 are set to be active (for example, at a high level) and both select transistor ST00 and block transistor BT0 are set to be turned on.

In addition, an electric potential of word line WL0 is set to be active (for example, at a high level), and electric potentials of other word lines WL1, WL(i−2), and WL(i−1) are set to be nonactive (for example, at a low level). At this time, cell transistor CT00 is set to be turned on, and other cell transistors CT10, CT(i−2)0, and CT(i−1)0 are set to be turned off.

In this state, a potential V1 is applied to the global bit line GBL while an electric potential V2 is applied to the global source line GSL.

When V1 is greater than V2, for example, “0” (low resistance state) is written to resistance change element RE00 since write current Iw flows from the local bit line LBL to the local source line LSL.

In addition, when V1 is smaller than V2, for example, “1” (high-resistance state) is written to resistance change element RE00 since write current Iw flows from the local source line LSL to the local bit line LBL.

As for reading, the read current may be flown to resistance change element RE00 in the same manner as that explained above. However, the read current may be flown in one direction and needs to be sufficiently smaller than the write current.

### 4. APPLICATION EXAMPLE

A processor employed in a portable information terminal is required to consume little energy. As one of methods for reducing the energy consumed by a processor, a cache memory based on a static random access memory (SRAM) requiring great standby power is replaced with a nonvolatile semiconductor memory using a nonvolatile element.

In other words, leakage power of the SRAM tends to be greater both during operation and during standby (non-operation) as the transistor becomes smaller. For this reason, the power supply can be shut down during standby and the power consumption during standby can be reduced by replacing the cache memory with a nonvolatile semiconductor memory.

Thus, a low-power processor can be implemented by employing the magnetic random access memory (MRAM) as the cache memory.

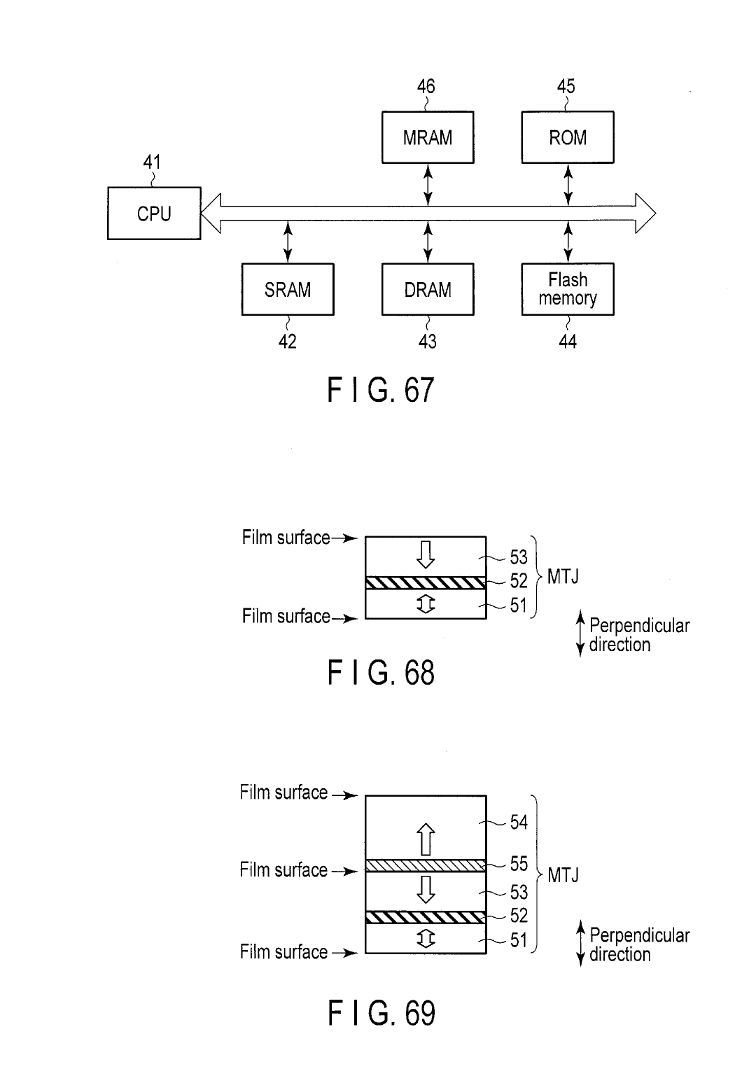

FIG. 67 shows an example of a low-power processor system.

A CPU 41 controls an SRAM 42, a DRAM 43, a flash memory 44, a ROM 45 and a magnetic random access memory (MRAM) 46.

The MRAM 46 can be used as a replacement for the SRAM 42, the DRAM 43, the flash memory 44 or the ROM 45. In accordance with this, at least any one of the SRAM 42, the DRAM 43, the flash memory 44 and the ROM 45 may be omitted.

The MRAM 46 can be used as a nonvolatile cache memory (for example, L2 cache).

FIG. 68 shows a basic structure of the magnetoresistive element.

The magnetoresistive element MTJ has a multilayered structure in which a storage layer (ferromagnetic layer) 51 having perpendicular and variable magnetization, a tunnel barrier layer (nonmagnetic layer) 52, and a reference layer (ferromagnetic layer) 53 having perpendicular and fixed magnetization are disposed in this order in a direction perpendicular to a film surface.

Fixed magnetization means that the direction of magnetization is not changed before and after writing, and variable magnetization means that the direction of magnetization can be changed oppositely before and after writing.

In addition, writing indicates spin transfer writing which supplies a spin torque to the magnetization of the storage layer 1 by allowing a spin implantation current (spin-polarized electrons) to flow to the magnetoresistive element MTJ.

For example, when the spin implantation current is made to flow from the storage layer 51 toward the reference layer 53, the direction of magnetization of the storage layer 51 becomes the same as the direction of magnetization of the reference layer 53 (parallel state) since the spin-polarized electrons are implanted into the storage layer 51 in the same direction as the magnetization of the reference layer 53 to supply a spin torque to the magnetization inside the storage layer 51.

In addition, when the spin implantation current is flown from the reference layer 53 toward the storage layer 51, the direction of magnetization of the storage layer 51 becomes opposite to the direction of magnetization of the reference layer 53 (antiparallel state) since electrons spin-polarized in a direction opposite to the magnetization of the reference layer 53, of the electrons forwarding from the storage layer 51 toward the reference layer 53, are returned into the storage layer 51 to supply a spin torque to the magnetization inside the storage layer 51.

The resistance value of the magnetoresistive element MTJ changes because of the magnetoresistive effect, depending on the relative directions of magnetization of the reference layer 53 and the storage layer 51. In other words, the resistance value of the magnetoresistive element MTJ becomes lower in the parallel state and higher in the antiparallel state. A value defined by (R1−R0)/R0 where R0 is the resistance value in the parallel state and R1 is the resistance value in the antiparallel state is called the magnetoresistive (MR) ratio.

In the present example, the magnetization of the reference layer 53 is fixed in a state of being oriented to the storage layer 51 side, but may be fixed in a state of being oriented to a side opposite to the storage layer 51. In addition, when the magnetoresistive element MTJ is disposed on the semiconductor substrate, the positional relationship in the vertical direction between the reference layer 53 and the storage layer 51 is not limited.

For example, when the reference layer 53 is disposed at an upper position than the storage layer 51, the magnetoresistive element MTJ is called a top-pin type magnetoresistive element and, when the reference layer 53 is disposed at a lower position than the storage layer 51, the magnetoresistive element MTJ is called a bottom-pin type magnetoresistive element.

FIG. 69 shows an example of a magnetoresistive element comprising a shift cancel layer.

The magnetoresistive element MTJ has a multilayered structure in which a storage layer (ferromagnetic layer) 51 having perpendicular and variable magnetization, a tunnel barrier layer (nonmagnetic layer) 52, and a reference layer (ferromagnetic layer) 53 having perpendicular and fixed magnetization are disposed in this order in the perpendicular direction.

In addition, the magnetoresistive element MTJ comprises a shift cancelling layer (ferromagnetic layer) 54 having perpendicular and fixed magnetization, on the reference layer 53 side. A nonmagnetic layer (for example, metal layer) 55 is disposed between the reference layer 53 and the shift cancelling layer 54.

In the present example, the reference layer 53 and the storage layer 51 have perpendicular magnetization. In this case, since a stray magnetic field from the reference layer 53 is oriented in the direction of magnetization (perpendicular direction) of the storage layer 51, a stray magnetic field having a great perpendicular component is applied to the storage layer 51. The stray magnetic field acts in a direction of setting the direction of magnetization of the storage layer 51 to be the same as the direction of magnetization of the reference layer 53 (parallel state).

An RH curve of the storage layer 51 is therefore shifted.

In other words, when the magnetoresistive element MTJ is changed from the antiparallel state to the parallel state, a small spin implantation current needs only to be made to flow to the magnetoresistive element MTJ and, when the magnetoresistive element MTJ is changed from the parallel state to the antiparallel state, a large spin implantation current must be made to flow to the magnetoresistive element MTJ.

In addition, the antiparallel state becomes unstable because of the stray magnetic field from the reference layer 53.

In other words, if the stray magnetic field becomes greater than the magnetic coercive force of the storage layer 51, the storage layer 51 cannot maintain the antiparallel state. In addition, even when the stray magnetic field is smaller than the magnetic coercive force of the storage layer 51, the magnetization of the storage layer 51 is often reversed from the antiparallel state to the parallel state by the stray magnetic field, in consideration of fluctuation of the magnetization caused by the thermal agitation.

The shift cancelling layer 54 is disposed to solve this problem.

In the present example, the reference layer 53 and the shift cancelling layer 54 are laminated on each other. In this case, the direction of magnetization of the shift cancelling layer 54 is set to be opposite to the direction of magnetization of the reference layer 53. Thus, the stray magnetic field from the reference layer 53 can be canceled by a canceling magnetic field from the shift cancelling layer 54, in the storage layer 51, and the shift of the RH curve of the storage layer 51 can be canceled.

### 5. CONCLUSION

According to the embodiments, when the vertical transistors are employed as cell transistors, small cell transistors of high driving power and high reliability can be implemented since gate patterning (word line patterning) can easily be executed even if the cell transistors are miniaturized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A resistance change memory comprising:
a first conductive region;
first and second semiconductor pillars on the first conductive region;
a first word line including a first portion surrounding a side surface of the first pillar, a second portion surrounding a side surface of the second pillar, and a third portion connecting between the first and second portions, the first and second portions being physically separated from one another;
a first resistance change element connected to an upper portion of the first semiconductor pillar;
a second resistance change element connected to an upper portion of the second semiconductor pillar;
a first bit line connected to the first resistance change element; and
a second bit line connected to the second resistance change element.

2. The memory of claim 1, further comprising:
an air gap between the first and second portions.

3. The memory of claim 1, further comprising:
a first electrode between the first semiconductor pillar and the first resistance change element; and
a second electrode between the second semiconductor pillar and the second resistance change element.

4. The memory of claim 1, wherein
each of the first and second electrodes includes a conductive semiconductor having impurities.

5. The memory of claim 1, wherein
upper ends of the first and second portions are lower than upper ends of the first and second electrodes.

6. The memory of claim 1, wherein
each of thicknesses of the first and second portions in a direction in which the first and second pillars are arranged is substantially equal to a thickness of the third portion in a direction in which the first and second pillars extend.

7. The memory of claim 1, further comprising:
a third semiconductor pillar on the first conductive region, the third semiconductor pillar being adjacent to the first semiconductor pillar in a direction intersecting a direction in which the first and second semiconductor pillars are arranged;
a second word line including a fourth portion surrounding a side surface of the third pillar, the fourth portion being physically separated from the first and second portions; and
a third resistance change element connected to an upper portion of the third semiconductor pillar,
wherein the first bit line is connected to the third resistance change element.

8. The memory of claim 7, wherein
the first and second word lines extend in a direction in which the first and second semiconductor pillars are arranged.

9. The memory of claim 7, wherein
the first and second bit lines extend in a direction in which the first and third semiconductor pillars are arranged.

10. The memory of claim 1, wherein
the first conductive region is an impurity region in a semiconductor substrate.

11. The memory of claim 1, further comprising:
sub-arrays each including the first conductive region, the first and second semiconductor pillars, the first word line, the first and second resistance change elements, and the first and second bit lines;
a first conductive line connected to the first and second bit lines in each of the sub-arrays; and
a second conductive line connected to the conductive region in each of the sub-arrays.

12. The memory of claim 11, further comprising:
a transistor connected between the first conductive line and one of the first and second bit lines,
wherein the transistor comprises:
a second conductive region;
a third semiconductor pillars on the second conductive region; and
a gate line surrounding a side surface of the third semiconductor pillar.

13. The memory of claim 11, further comprising:
a transistor connected between the second conductive line and the first conductive region,
wherein the transistor comprises:
a third semiconductor pillars on the first conductive region; and
a gate line surrounding a side surface of the third semiconductor pillar.

14. The memory of claim 11, further comprising:
a transistor connected between the second conductive line and the first conductive region,
wherein the transistor comprises:
a second conductive region;
a third semiconductor pillars on the second conductive region; and
a gate line surrounding a side surface of the third semiconductor pillar.

15. The memory of claim 1, wherein
the first and second resistance change elements are provided directly above the first and second semiconductor pillars respectively.

16. A method of manufacturing the memory of claim 1, the method comprising:
patterning the first and second semiconductor pillars by using first and second insulating layers as a mask;
forming a conductive layer covering the first and second semiconductor pillars and the first and second insulating layers, and not filling between the first and second semiconductor pillars; and
forming the first word line by pattering the conductive layer.

17. The method of claim 16, further comprising:
forming the first conductive region by executing an ion implantation using the first and second insulating layers as a mask.

18. The method of claim 16, further comprising:
forming a third insulating layer covering the first and second insulating layers after patterning the conductive layer; and
exposing the upper portions of the first and second semiconductor pillars by chemical mechanical polishing the first, second and third insulating layers and the conductive layer.

19. The method of claim 18, further comprising:
forming first and second electrodes on the first and second semiconductor pillars by an epitaxial growth respectively after exposing the upper portions of the first and second semiconductor pillars.

20. The method of claim 18, further comprising:
forming a fourth insulating layer covering the first and second semiconductor pillars after exposing the upper portions of the first and second semiconductor pillars, an air gap being formed between the first and second semiconductor pillars by forming the fourth insulating layer.

21. The method of claim 19, further comprising:
forming a third insulating layer covering the first and second pillars and having first and second opening portions extending to the upper portions of the first and second semiconductor pillars, after exposing the upper portions of the first and second pillars, and
forming the first and second electrodes contacting the upper portions in the first and second opening portions.
